(19) United States
(12) Patent Application Publication
(10) Pub. No.: US 2026/0229765 A1
(43) Pub. Date: Aug. 6, 2026

(54) PACKAGE ANTENNAS

(71) Applicant: TEXAS INSTRUMENTS INCORPORATED, Dallas, TX (US)

(72) Inventors: Juan HERBSOMMER, Allen, TX (US); Hassan Omar ALI, Murphy, TX (US)

(21) Appl. No.: 19/043,318

(22) Filed: Jan. 31, 2025

(51) Int. Cl. H01Q 1/22; H01Q 7/00; H01Q 9/04; H10W 70/40; H10W 74/10

(52) U.S. Cl. CPC H01Q 1/2283; H01Q 7/00; H01Q 9/0407; H10W 70/464; H10W 74/111

(57) ABSTRACT

In examples, a semiconductor package includes a die pad extending in a horizontal direction and a semiconductor die coupled to the die pad, the semiconductor die having a device side in which circuitry is formed. The package includes a conductive terminal coupled to the device side of the semiconductor die by a bond wire and an antenna vertically distanced from the die pad and extending in the horizontal direction. The package includes a metal member extending from the antenna in the horizontal direction and a conductive member coupling the antenna to the conductive terminal. The package includes a mold compound contacting the die pad, the semiconductor die, the conductive terminal, the antenna, the metal member, and the conductive member. A portion of the conductive terminal and the metal member are exposed on one or more exterior lateral surfaces of the mold compound.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die may then be coupled to a substrate or die pad. The resulting structure may be subsequently covered with a mold compound to produce a package.

### SUMMARY

In examples, a semiconductor package includes a die pad extending in a horizontal direction and a semiconductor die coupled to the die pad, the semiconductor die having a device side in which circuitry is formed. The package includes a conductive terminal coupled to the device side of the semiconductor die by a bond wire and an antenna vertically distanced from the die pad and extending in the horizontal direction. The package includes a metal member extending from the antenna in the horizontal direction and a conductive member coupling the antenna to the conductive terminal. The package includes a mold compound contacting the die pad, the semiconductor die, the conductive terminal, the antenna, the metal member, and the conductive member. A portion of the conductive terminal and the metal member are exposed on one or more exterior lateral surfaces of the mold compound.

In examples, a method for manufacturing a semiconductor package includes coupling a semiconductor die to a die pad of a first lead frame, where the semiconductor die has a device side in which circuitry is formed, and the first lead frame includes a conductive terminal. The method includes coupling a bond wire to the device side of the semiconductor die and to the conductive terminal, and positioning a second lead frame above the semiconductor die and the first lead frame. The second lead frame includes an antenna and a conductive member. The method includes coupling a bent conductive member of the second lead frame to the conductive terminal. The method includes applying a mold compound covering the semiconductor die, the bond wire, and the first and second lead frames. The conductive terminal is exposed on an exterior lateral surface of the mold compound.

### BRIEF DESCRIPTION OF THE DRAWINGS

FIG. 1 is a block diagram of an electronic device including semiconductor packages having package antennas, in accordance with various examples.

FIGS. 2A, 2B, 2C, and 2D are perspective, top-down, profile, and profile views of a semiconductor package including a package antenna, in accordance with various examples.

FIG. 3 is a graph depicting the performance of a semiconductor package including a package antenna, in accordance with various examples.

FIG. 4 is a schematic diagram depicting the radiation pattern of a semiconductor package including a package antenna, in accordance with various examples.

FIGS. 5A, 5B, 5C, and 5D are perspective, top-down, profile, and profile views of a semiconductor package including a package antenna, in accordance with various examples.

FIG. 6 is a graph depicting the performance of a semiconductor package including a package antenna, in accordance with various examples.

FIGS. 7A and 7B are schematic diagrams depicting the radiation pattern of a semiconductor package including a package antenna, in accordance with various examples.

FIGS. 8A and 8B are schematic diagrams depicting the radiation pattern of a semiconductor package including a package antenna, in accordance with various examples.

FIGS. 9A, 9B, 9C, and 9D are perspective, cross-sectional, profile, top-down, and perspective views of a semiconductor package including a package antenna, in accordance with various examples.

FIG. 9E is a perspective view of a semiconductor package including a package antenna, in accordance with various examples.

FIG. 10 is a graph depicting the performance of a semiconductor package including a package antenna, in accordance with various examples.

FIG. 11 is a graph depicting the performance of a semiconductor package including a package antenna, in accordance with various examples.

FIGS. 12A, 12B, 12C, and 12D are perspective, top-down, profile, and profile views of a semiconductor package including a package antenna, in accordance with various examples.

FIG. 13 is a graph depicting the performance of a semiconductor package including a package antenna, in accordance with various examples.

FIGS. 14A, 14B, 14C, and 14D are top-down, perspective, profile, and profile views of a semiconductor package including a package antenna, in accordance with various examples.

FIG. 15 is a graph depicting the performance of a semiconductor package including a package antenna, in accordance with various examples.

FIG. 16 is a graph depicting the performance of a semiconductor package including a package antenna, in accordance with various examples.

FIG. 17 is a graph depicting the performance of a semiconductor package including a package antenna, in accordance with various examples.

FIG. 18 is a flow diagram of a method for manufacturing a semiconductor package including a package antenna, in accordance with various examples.

FIGS. 19A, 19B, 19C, 19D, 19E, and 19F are a process flow of a method for manufacturing a semiconductor package including a package antenna, in accordance with various examples.

FIGS. 20A, 20B, 20C, 20D, 20E, and 20F are a process flow of a method for manufacturing a semiconductor package including a package antenna, in accordance with various examples.

FIGS. 21A, 21B, 21C, 21D, 21E, and 21F are a process flow of a method for manufacturing a semiconductor package including a package antenna, in accordance with various examples.

FIG. 22 is a flow diagram of a method for manufacturing a semiconductor package including a package antenna, in accordance with various examples.

FIGS. 23A, 23B, 23C, 23D, 23E, 23F, 23G, 23H, 23I, 23J, 23K1, 23K2, 23K3, 23L1, 23L2, and 23L3 are a process flow of a method for manufacturing a semiconductor package including a package antenna, in accordance with various examples.

### DETAILED DESCRIPTION

Different package types are suited to various applications and budgetary constraints, with some specifically designed to support wireless technologies. High-frequency wireless communications, such as 2.4 GHz Bluetooth and Wi-Fi, use antennas of a precise length (e.g., one-quarter wavelength) for efficient operation. Low-cost packages like small outline transistor (SOT) and small outline integrated circuit (SOIC) packages lack the physical space to integrate these relatively long antennas. Consequently, in such applications, antennas are placed externally to the package, such as on a printed circuit board (PCB).

While positioning antennas on PCBs enables the use of small, low-cost packages, it also consumes valuable PCB area, increasing cost and reducing opportunities for system miniaturization. Additionally, circuits driving PCB antennas often interface through large package leads, which can introduce impedance parasitics due to the large lead size. These parasitics degrade the performance of wireless communication, posing further challenges for integrating high-frequency functionality in compact and economical packages (e.g., SOT packages).

This description presents various examples of small, low-cost packages that integrate high-frequency antennas, thus mitigating the technical challenges described above. More specifically, at least some of the packages described herein include antennas, such as patch antennas, loop antennas, and meander line antennas (MLAs), that are vertically distanced from the semiconductor die, the die pad, and the conductive terminals (e.g., leads) of the package. The antenna is coupled to a conductive terminal of the package by a conductive member, such as a gang clip. Through this connection, the semiconductor die is able to send electrical signals to and receive electrical signals from the antenna. By positioning the antenna in a different horizontal plane than the remaining components of the semiconductor package, additional space is made available to facilitate high-frequency operations. In examples, a semiconductor package includes a die pad extending in a horizontal direction and a semiconductor die coupled to the die pad. The semiconductor die has a device side in which circuitry is formed. The semiconductor package also includes a conductive terminal coupled to the device side of the semiconductor die by a bond wire and an antenna vertically distanced from the die pad and extending in the horizontal direction. The semiconductor package includes a metal member extending from the antenna in the horizontal direction and a conductive member coupling the antenna to the conductive terminal. The semiconductor package includes a mold compound contacting the die pad, the semiconductor die, the conductive terminal, the patch antenna, the metal member, and the conductive member. The conductive terminal and the metal member are exposed on one or more exterior lateral surfaces of the mold compound.

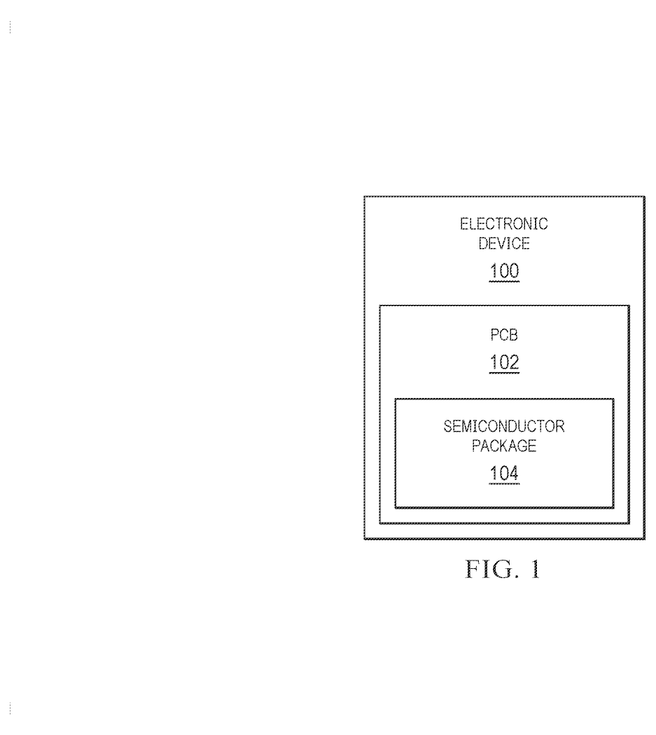

FIG. 1 is a block diagram of an electronic device including semiconductor packages having package antennas, in accordance with various examples. More particularly, FIG. 1 depicts a block diagram of an electronic device 100 including a printed circuit board (PCB) 102. The electronic device 100 also includes a semiconductor package 104 that is coupled to the PCB 102 (e.g., by solder joints). Examples of the electronic device 100 include an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system. In examples, the electronic device 100 is a wireless device. In examples, the semiconductor package 104 is configured to perform one or more wireless operations, such as the transmission and reception of wireless signals.

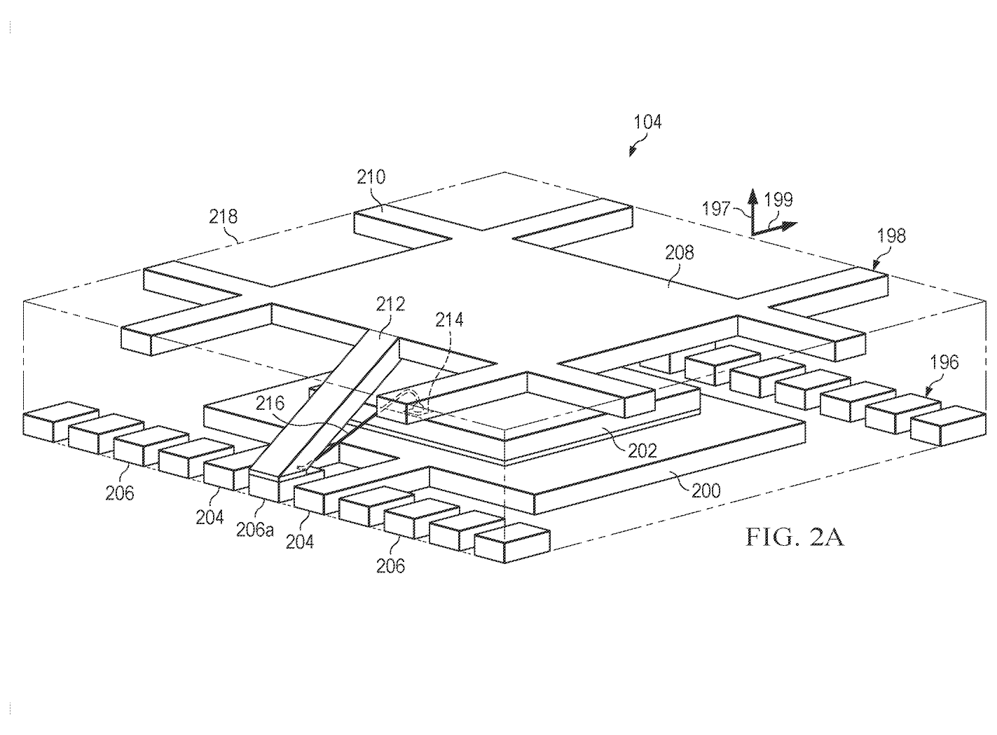

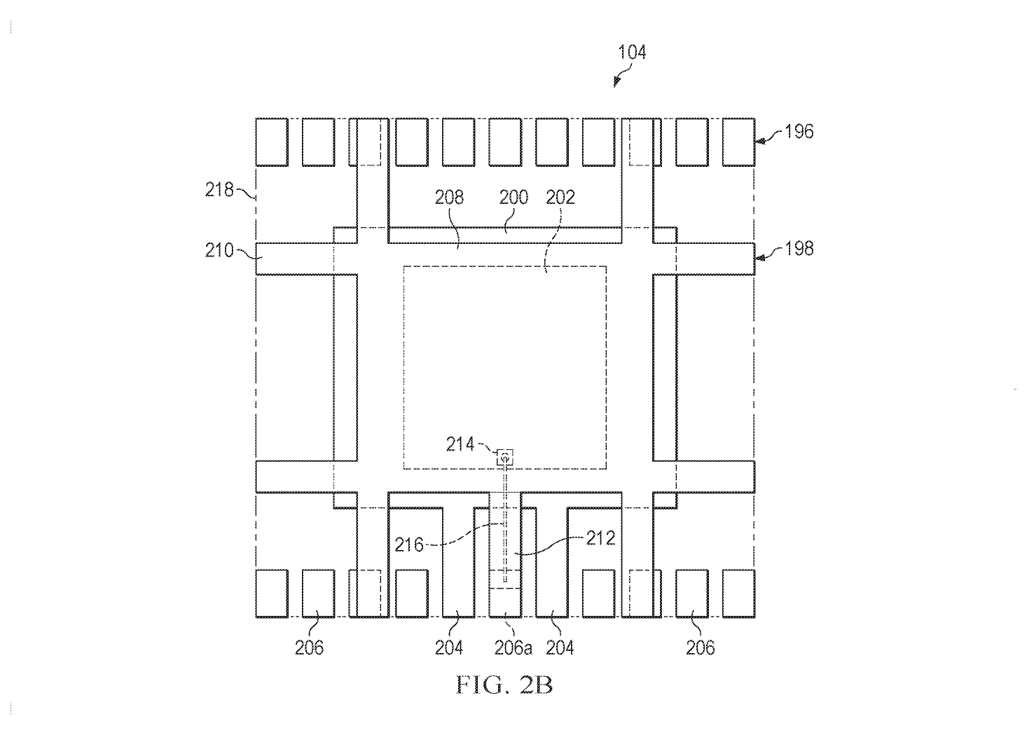

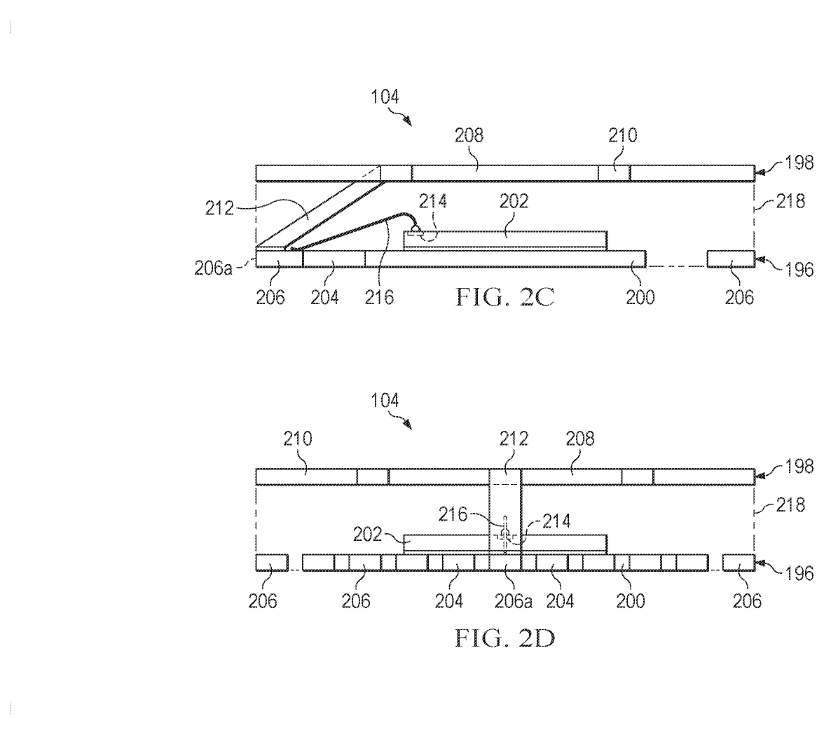

FIGS. 2A, 2B, 2C, and 2D are perspective, top-down, profile, and profile views of a semiconductor package including a package antenna, in accordance with various examples. In particular, FIGS. 2A-2D depict various examples of the semiconductor package 104 (e.g., the semiconductor package 104 of FIG. 1). The semiconductor package 104 includes a portion of a lead frame 196 and a portion of a lead frame 198. The portions of the lead frames 196 and 198 are positioned in different horizontal planes of the semiconductor package 104 and are formed from separate lead frames during manufacture of the semiconductor package 104. The portion of the lead frame 196 includes a die pad 200, a semiconductor die 202 coupled to the die pad 200 (e.g., by a die attach material), one or more tie bars 204 contacting the die pad 200, and package pins 206 (e.g., a package pin 206a). A bond wire 216 is coupled to a bond pad 214 on the semiconductor die 202 and is also coupled to the package pin 206a. Additional bond wires 216 may couple the semiconductor die 202 to other package pins 206. The portion of the lead frame 198 includes an antenna 208 (e.g., a patch antenna), tie bars 210 contacting the antenna 208, and a clip 212 (also referred to herein as a gang clip because the clip is useful to couple multiple components of one or more lead frames together) contacting the antenna 208. The antenna 208, the tie bars 210, and the clip 212 form a single monolithic structure and are not coupled to each other. The clip 212 couples the antenna 208 to the package pin 206a, such as by a solder joint. During a reflow process, the solder that eventually forms the solder joint may flow across a top surface of the package pin 206a, and may approach the bond site of the bond wire 216 that is coupled to the package pin 206a (e.g., a stitch bond site). If the solder contacts and/or covers the bond site, the solder will damage the integrity of the bond. To mitigate this risk, the surface area of the top surface of the package pin 206a is sized so that there is a distance of at least 0.5 mm between the clip 212 and the bond site of the bond wire 216. A mold compound 218 covers the portions of the lead frames 196 and 198. The package pins 206, the clip 212, and the tie bars 210 are exposed on one or more exterior surfaces of the semiconductor package 104. The clip 212, as well as the other clips described herein, are downset clips, meaning that the clips extend in a downward and outward direction, away from a center of the semiconductor package 104. Thus, clips may be referred to herein as downsets.

Because the antenna 208 is a patch antenna, the size (i.e., surface area) of the antenna 208 is inversely proportional to the resonant frequency of the antenna 208. Larger surface areas correspond to lower resonant frequencies, and smaller surface areas correspond to higher resonant frequencies. Further, larger antennas 208 generally provide higher gain and directivity because they radiate or capture more energy over a given area. Larger antennas 208 support a higher bandwidth and better radiation efficiency. Other features of the antenna 208 may be impacted by the size of the antenna 208. The size of the antenna 208 should be selected accordingly. Stated another way, a mere segment of metal, such as a gang clipped structure, does not qualify as the antenna 208 because the antenna 208 is specifically sized and shaped to operate as a patch antenna and must be sized and shaped based on the factors described above to enable the semiconductor die 202 to operate the antenna 208 as an antenna. The antenna 208 must be sized proportional to the operating wavelength, such as wavelength divided by two or wavelength divided by four. To further facilitate such antenna operation, the antenna 208 has a horizontal surface area that is larger than a horizontal surface area of the semiconductor die 202; the antenna 208 covers and extends beyond the semiconductor die 202 in the top-down view (FIG. 2B); and the antenna 208 and the die pad 200 are approximately parallel to each other. A mold compound 218 covers the various structures of the semiconductor package 104.

The semiconductor die 202 is configured to communicate with the antenna 208 by way of the bond wire 216, the package pin 206a, and the clip 212. Accordingly, the semiconductor die 202 may transmit and/or receive wireless signals by way of the antenna 208. By including the antenna 208 within the semiconductor package 104, the technical challenges described above, such as PCB space consumption and parasitics, are avoided.

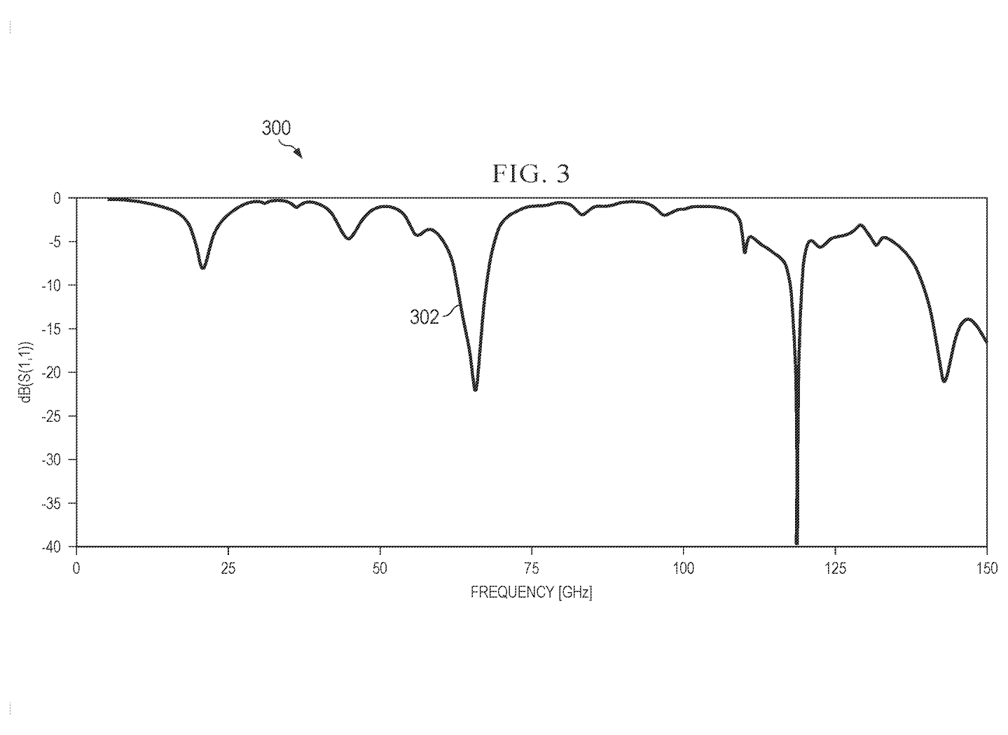

FIG. 3 is a graph 300 depicting the performance of a semiconductor package including a package antenna (e.g., the semiconductor package 104 in FIGS. 2A-2D), in accordance with various examples. The graph 300 includes frequency in GHz on the x-axis and return loss (S₁₁) in decibels (dB) on the y-axis. A curve 302 depicts the return loss for the antenna of the semiconductor package (e.g., the antenna 208 of the semiconductor package 104). The dips in the curve 302 depicted near 20.5 GHz, 64.2 GHz, 118.5 GHz, and 143.7 GHz indicate frequencies where the antenna 208 is well-matched to a feeding line (e.g., the clip 212).

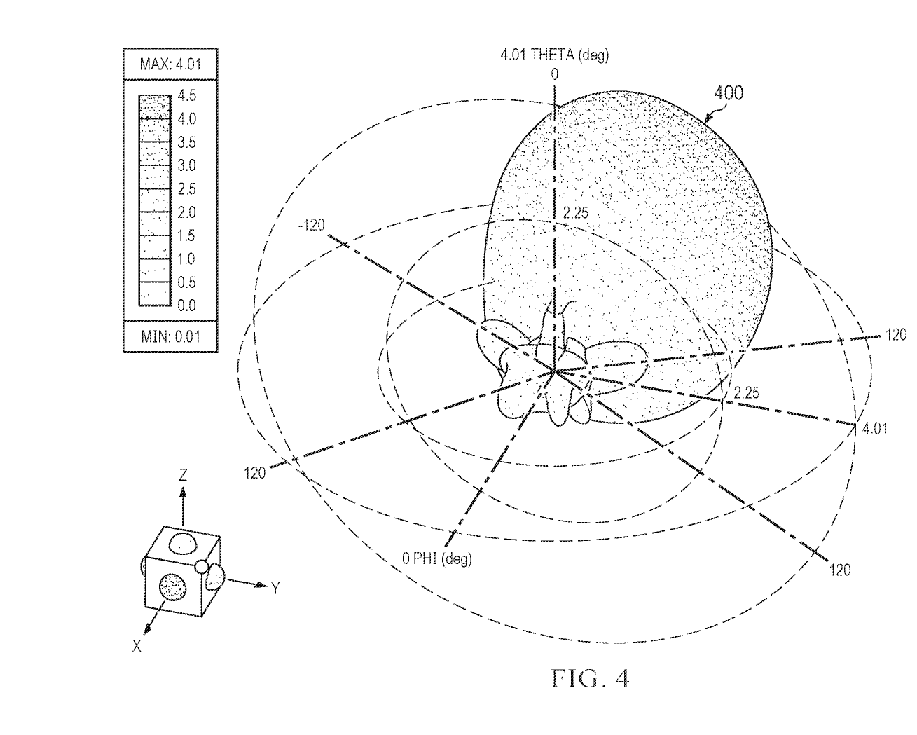

FIG. 4 is a schematic diagram depicting the radiation pattern 400 of a semiconductor package (e.g., the semiconductor package 104 in FIGS. 2A-2D) including a package antenna (e.g., the antenna 208), in accordance with various examples. The radiation pattern 400 indicates that the radiation of the antenna 208 is strongest in the positive Z direction. Referring to FIG. 2A, this is in the direction indicated by arrow 197. The radiation pattern 400 of FIG. 4 also indicates that the radiation of the antenna 208 is strongest in the negative X, positive Y quadrant, as arrow 199 in FIG. 2A depicts. Accordingly, the radiation pattern 400 may largely be characterized as unidirectional.

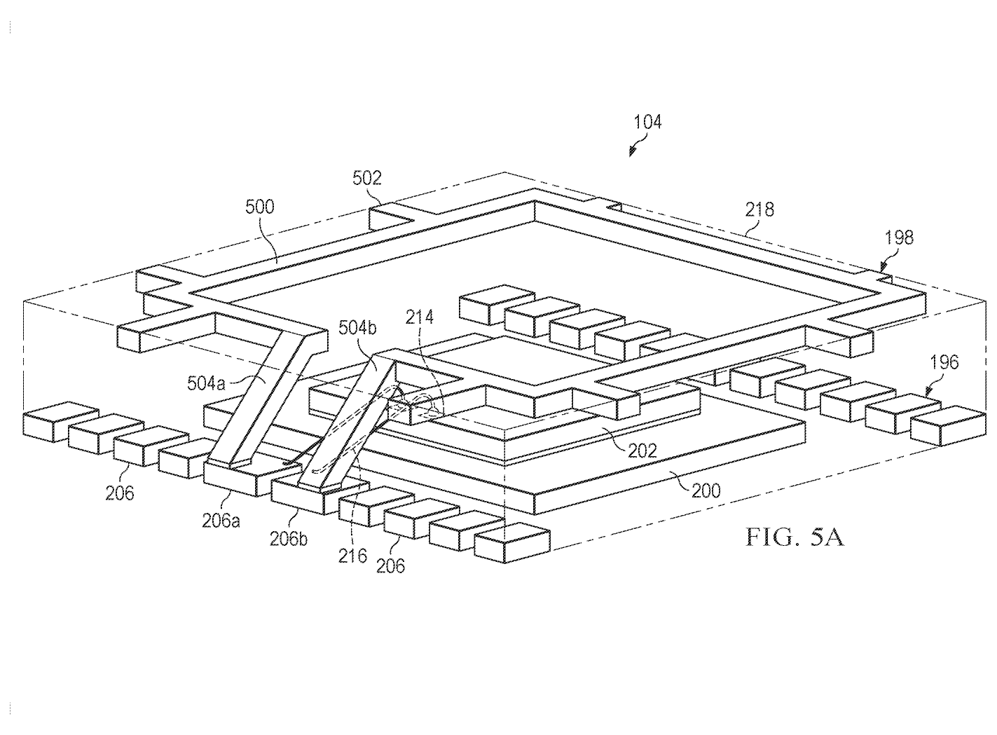

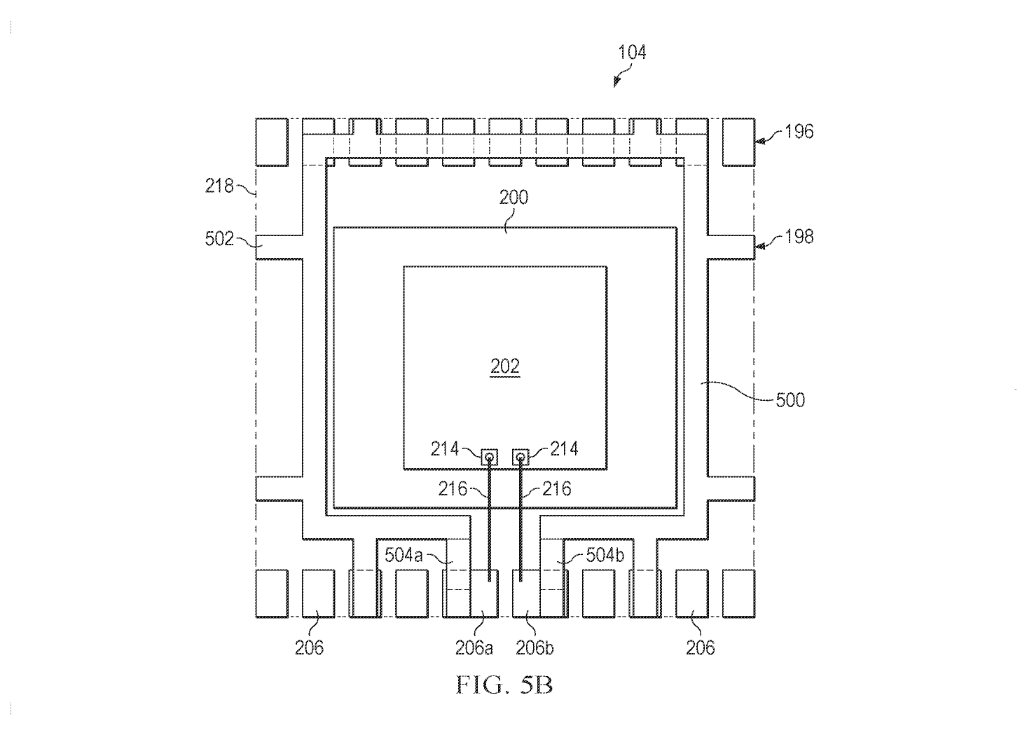

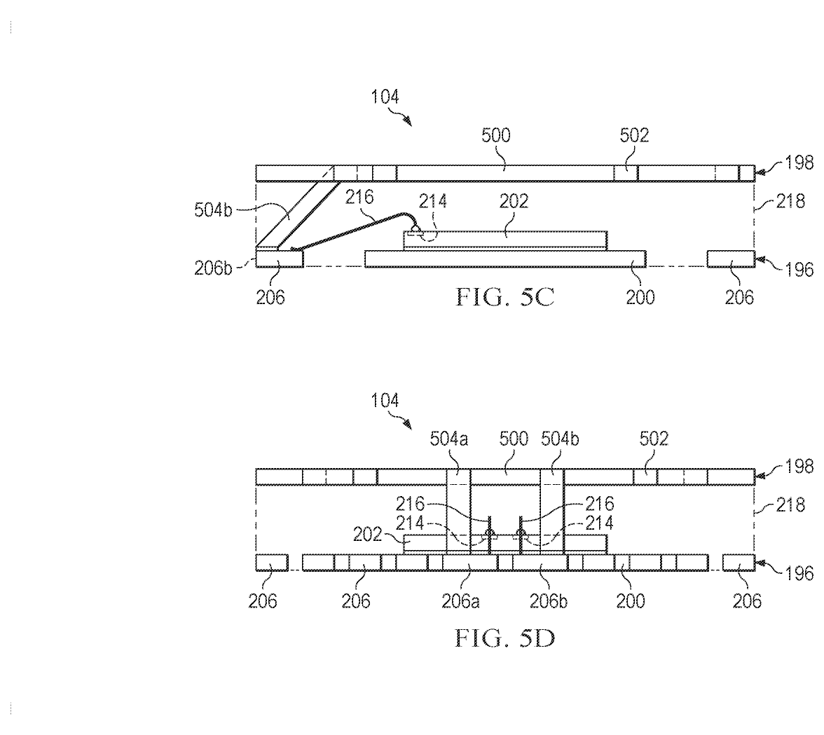

FIGS. 5A, 5B, 5C, and 5D are perspective, top-down, profile, and profile views of a semiconductor package including a package antenna, in accordance with various examples. More particularly, FIGS. 5A-5D depict another example semiconductor package 104 that may be included in the electronic device 100 of FIG. 1 but that is different in one or more aspects from the example semiconductor package 104 depicted in FIGS. 2A-2D. The semiconductor package 104 in FIGS. 5A-5D includes portions of a lead frame 196 and 198. The portion of the lead frame 196 in FIGS. 5A-5D is virtually identical to the portion of the lead frame 196 in FIGS. 2A-2D. The portion of the lead frame 198 in FIGS. 5A-5D differs from the portion of the lead frame 198 in FIGS. 2A-2D. Specifically, the portion of the lead frame 198 in FIGS. 5A-5D includes an antenna 500 (e.g., a line or loop antenna, a meander line antenna), tie bars 502 extending from the antenna 500 in an outward direction away from a center of the semiconductor package 104, and clips 504a and 504b. The clip 504a couples a first end of the antenna 500 to the package pin 206a (e.g., by a solder joint). The clip 504b couples a second end of the antenna 500 opposite the first end to a package pin 206b (e.g., by a solder joint). The portion of the lead frame 196 shown in FIGS. 5A-5D may differ from that shown in FIGS. 2A-2D in the inclusion of the package pin 206b, which is wider than other package pins of the semiconductor package 104 because it must accommodate the clip 504b and at least one of the bond wires 216, as shown. Similarly, the package pin 206a is wider than other package pins in the semiconductor package 104 because it must accommodate the clip 504a and at least one of the bond wires 216, as shown. In other examples, the bond wires 216 and the clips 504a, 504b may be positioned on the respective package pins 206a, 206b in such a manner that the package pins 206a, 206b can be the same width as the remaining package pins of the semiconductor package 104. The tie bars 502 are exposed on exterior, lateral surfaces of the mold compound 218. Similarly, the package pins 206 (e.g., the package pins 206a, 206b) are exposed on exterior, lateral surfaces of the mold compound 218.

The antenna 500 (e.g., a line antenna) may have operational properties based on the physical dimensions of the antenna 500. The length of the antenna 500 determines the resonant frequency of the antenna 500. For example, a half-wave dipole antenna has a resonant length of approximately lambda/2, where lambda is the wavelength in the medium. Wider antennas 500 will support wider bandwidths, because they reduce the characteristic impedance of the antenna 500, which can improve matching and reduce sensitivity to frequency changes.

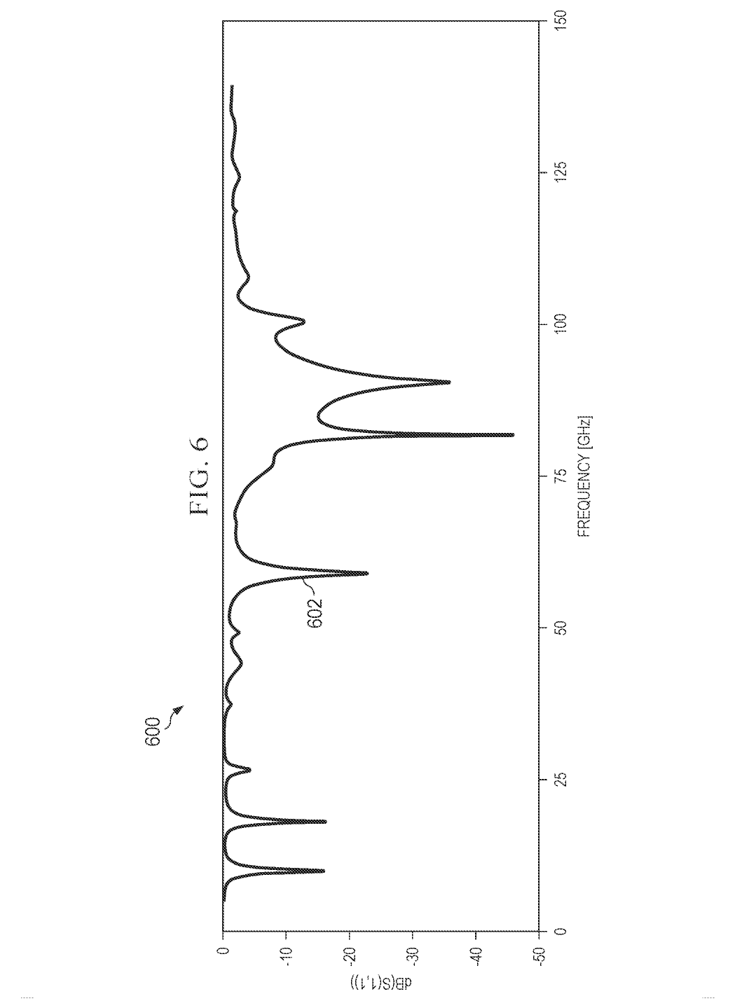

FIG. 6 is a graph 600 depicting the performance of a semiconductor package including a package antenna (e.g., the semiconductor package 104 in FIGS. 5A-5D), in accordance with various examples. The graph 600 includes frequency in GHz on the x-axis and return loss (S₁₁) in decibels (dB) on the y-axis. A curve 602 depicts the return loss for the antenna of the semiconductor package (e.g., the antenna 208 of the semiconductor package 104 in FIGS. 5A-5D). The dips in the curve 602 depicted near 10 GHz, 18.1 GHz, 58.9 GHz, 81.7 GHz, 89.9 GHz, and 100.5 GHz indicate frequencies where the antenna 208 is well-matched to a feeding line (e.g., the clips 504a, 504b).

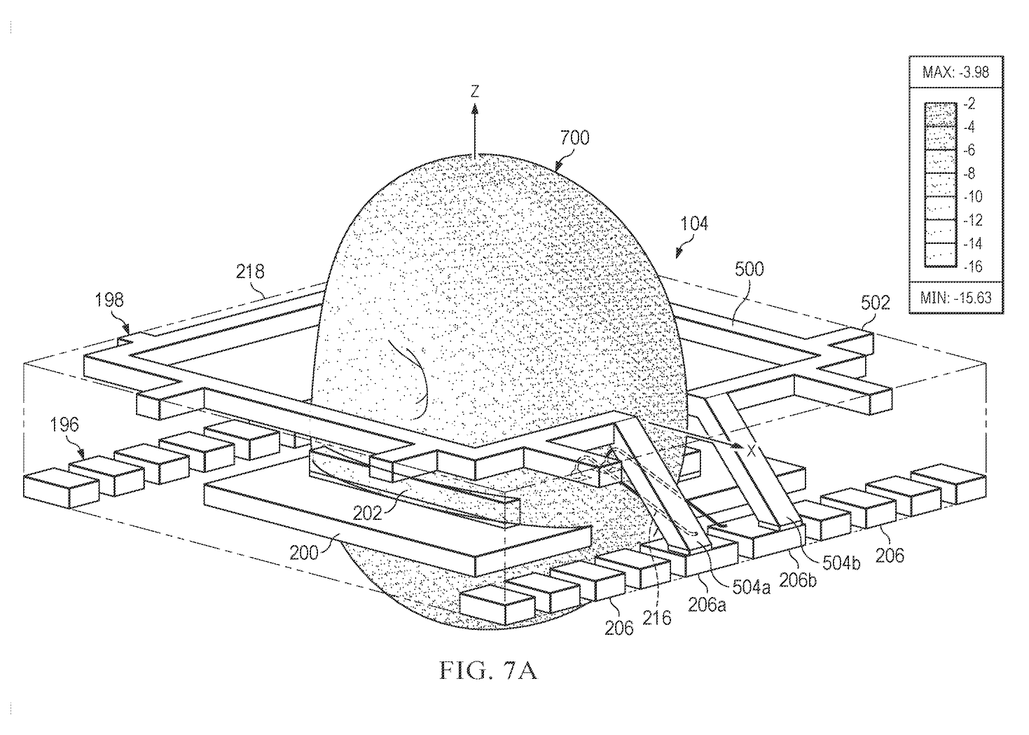

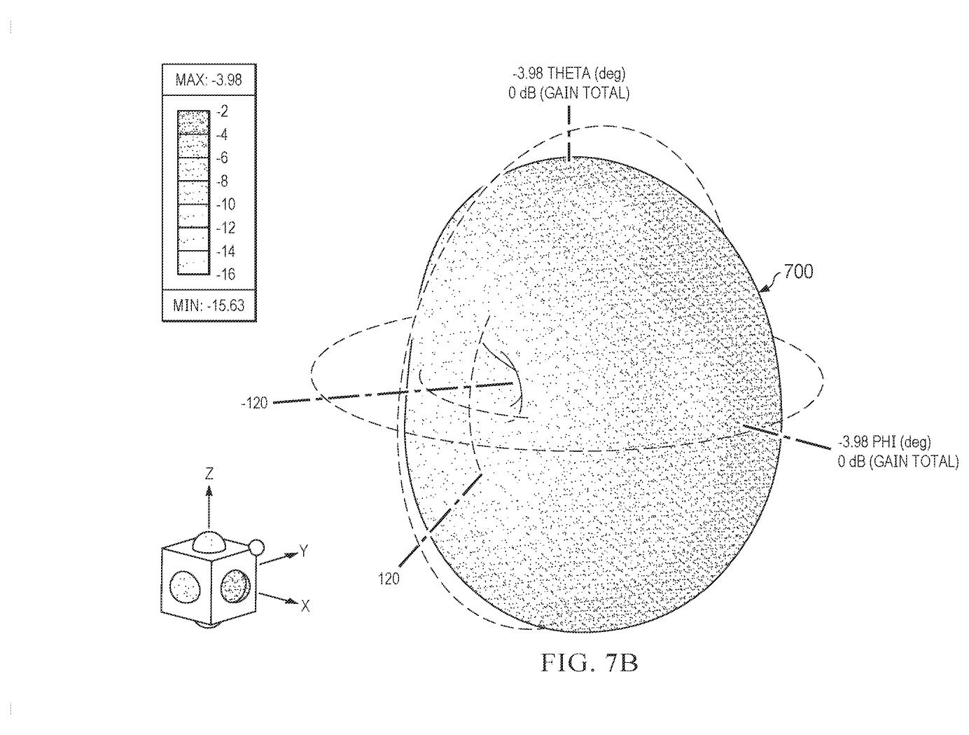

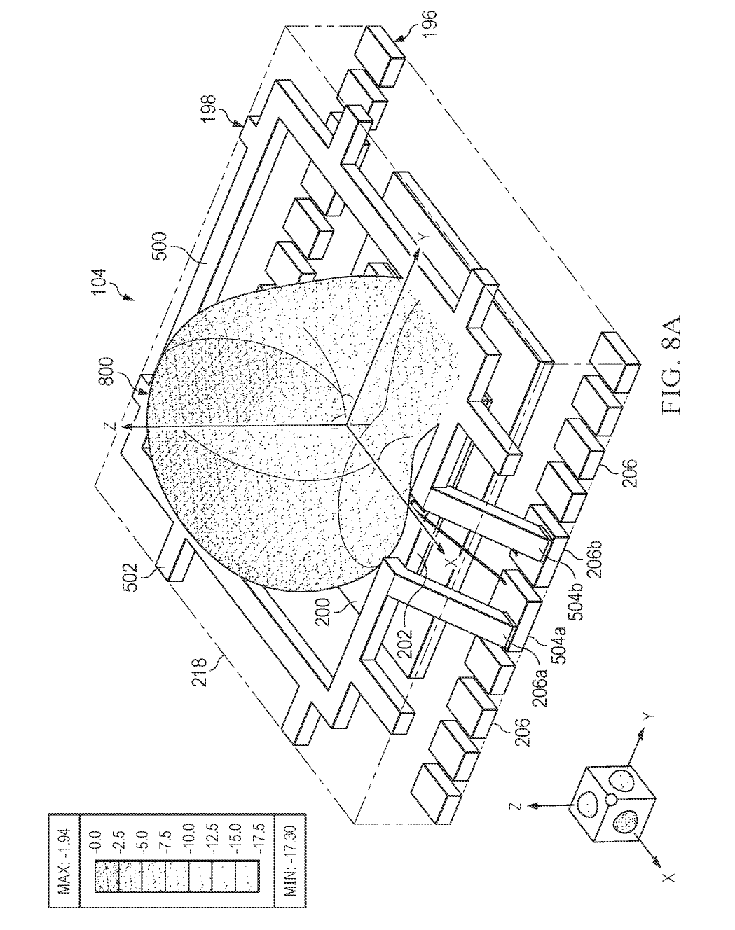

FIGS. 7A and 7B are schematic diagrams depicting the radiation pattern of a semiconductor package including a package antenna, in accordance with various examples. In particular, FIGS. 7A and 7B depict a radiation pattern 700 when the semiconductor package 104 of FIGS. 5A-5D is operating at approximately 10 GHz. As shown, the radiation pattern 700 is substantially symmetrical in shape. FIGS. 8A and 8B are schematic diagrams depicting the radiation pattern of a semiconductor package including a package antenna, in accordance with various examples. In particular, FIGS. 8A and 8B depict a radiation pattern 800 when the semiconductor package 104 of FIGS. 5A-5D is operating at approximately 18.1 GHz. As shown, the radiation pattern 800 is substantially asymmetrical in shape.

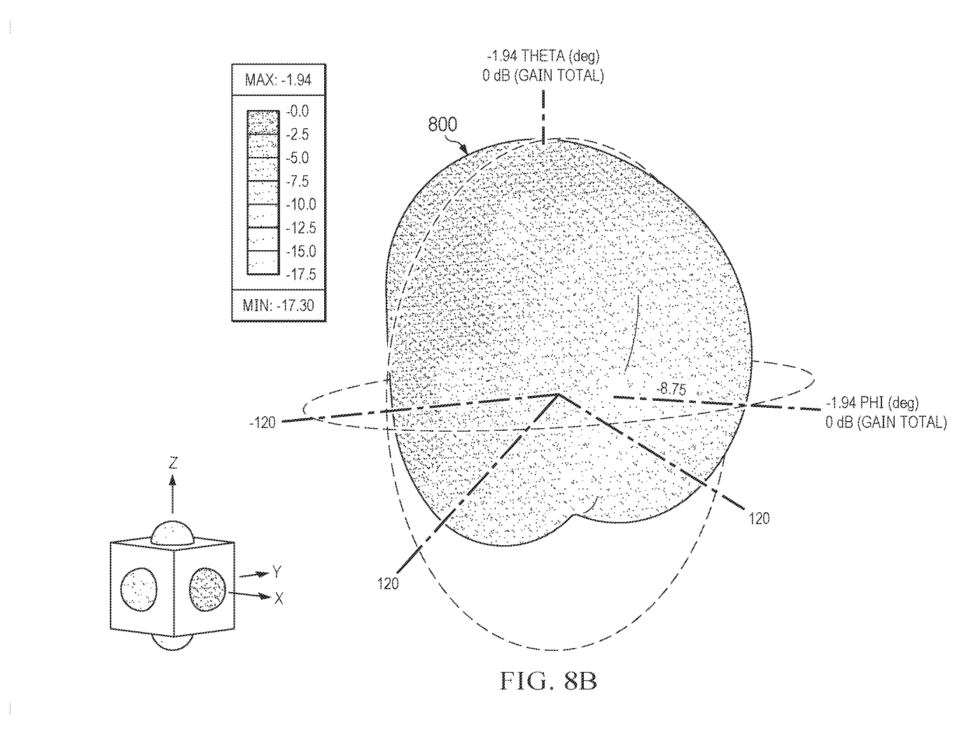

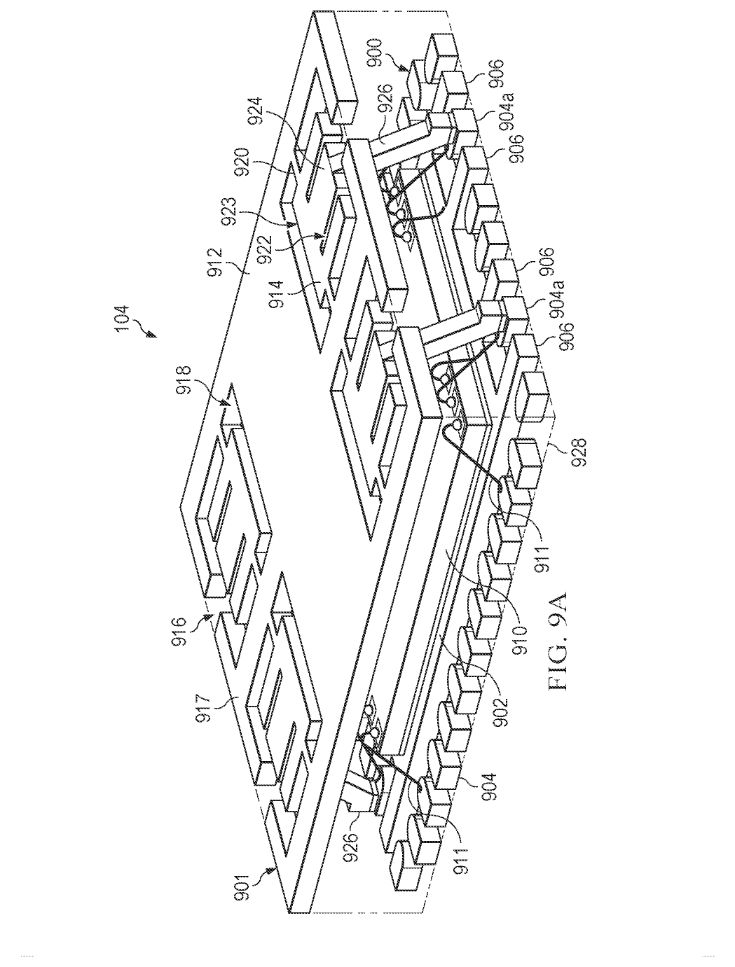

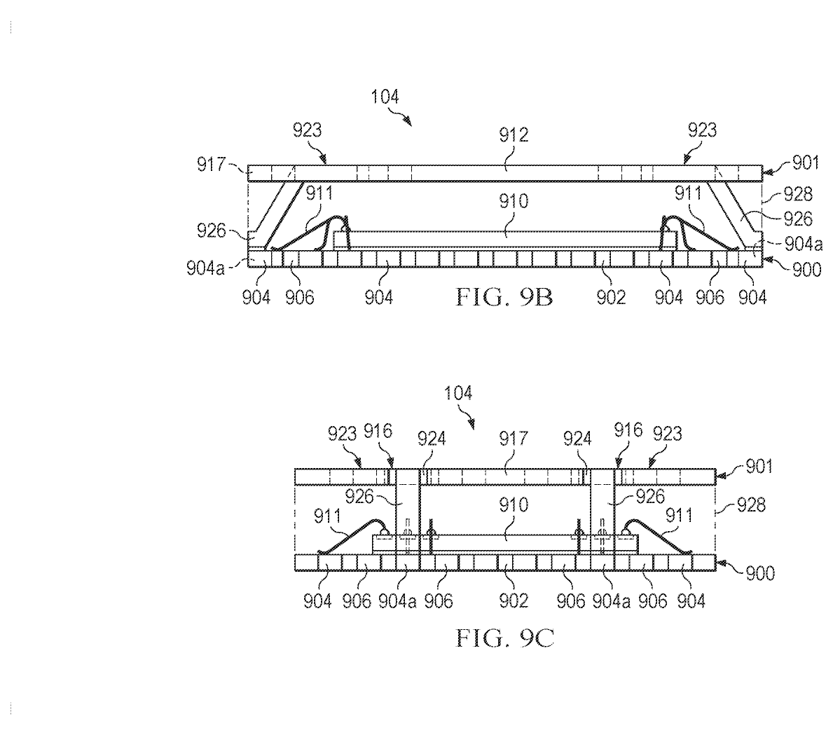

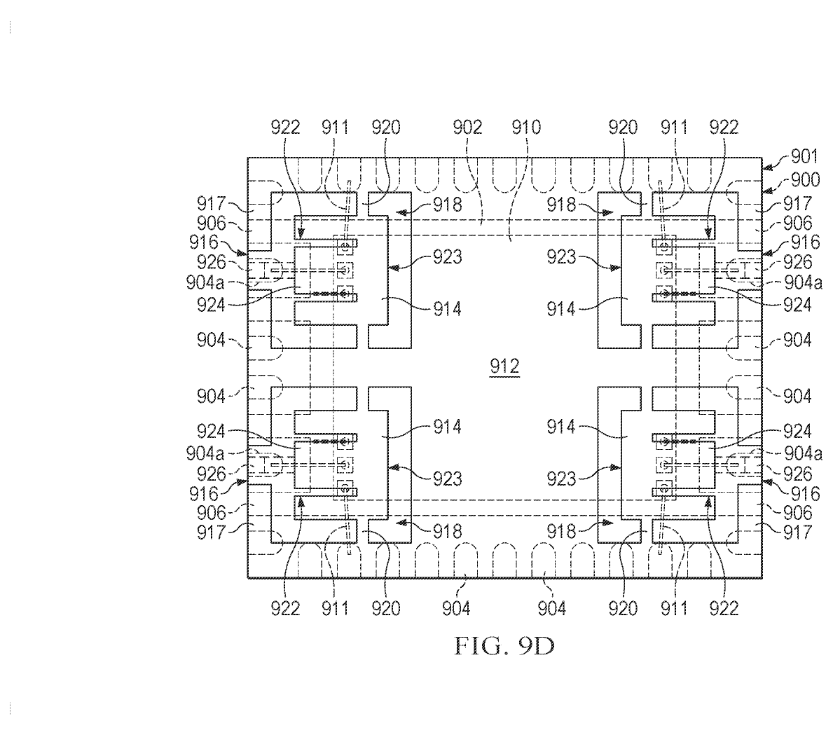

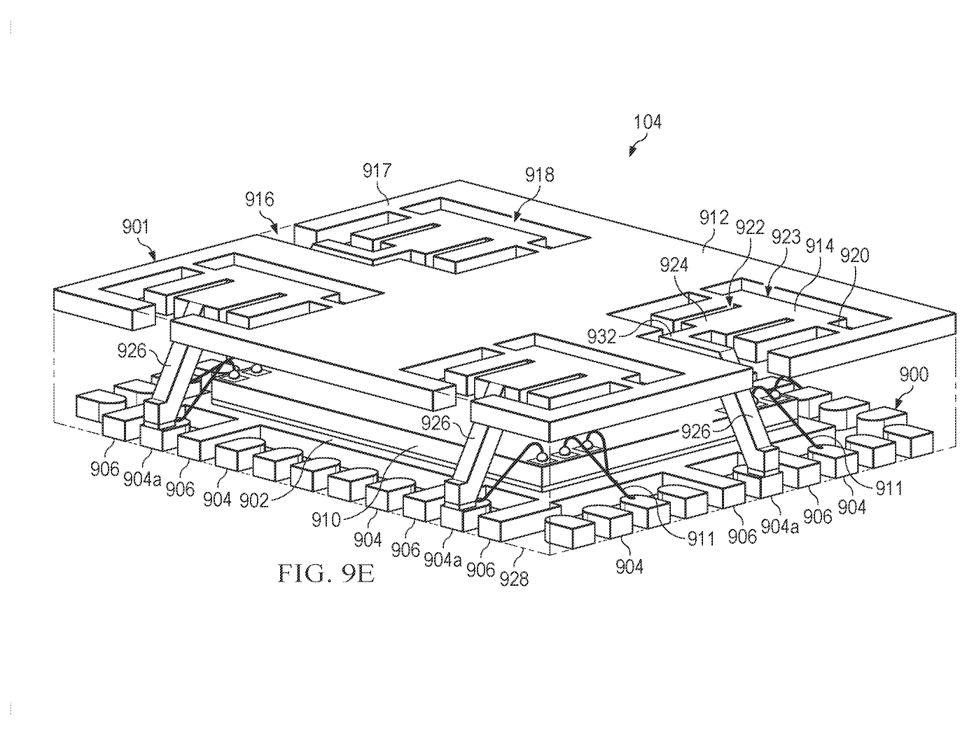

In some examples, a semiconductor package (e.g., semiconductor package 104) includes multiple antennas. FIGS. 9A, 9B, 9C, and 9D are perspective, cross-sectional, profile, top-down, and perspective views of a semiconductor package including a package antenna, in accordance with various examples. More particularly, FIGS. 9A-9D depict an example semiconductor package 104, such as may be included in the electronic device 100 of FIG. 1. The example semiconductor package 104 of FIGS. 9A-9D includes a portion of a lead frame 900 and a portion of a lead frame 901. The portion of the lead frame 900 includes a die pad 902 and package pins 904, including a package pin 904a. The semiconductor package 104, and thus the package pins 904, may be of a quad flat no lead (QFN) or a dual flat no lead (DFN) style. A tie bar 906 extends from the die pad 902 in an outward direction, away from a center of the semiconductor package 104. A semiconductor die 910 is coupled to the die pad 902 (e.g., using a suitable die attach material), and bond wires 911 couple a device side of the semiconductor die 910 in which circuitry is formed to one or more of the package pins 904, as shown.

The portion of the lead frame 901 includes a member 912. Openings 916 are present along a perimeter of the member 912. Specifically, each of the openings 916 is in a bar 917 that is approximately parallel to the members 920, and a vertical line extends through each opening 916 and through an end of a respective clip 926 (downset) that is distal to a respective antenna 923 (e.g., patch antenna). Each of the openings 916 is in communication with an opening 918. Each of the openings 918 surrounds an antenna 923. Each antenna 923 includes a member 914 having multiple openings 922 formed therein. Each pair of respective openings 922 defines a corresponding member 924. Members 920 (e.g., tie bars) couple the antennas 923 to the member 912 and suspend the antennas 923 in the openings 918. Downsets 926 and respective patch antennas 923 form single, monolithic structures that are substantially not coupled to each other at the desired antenna operating frequencies. Downsets 926 couple the members 924 to corresponding package pins 904, such as to the package pin 904a. Each of the clips 926 may couple to a respective package pin 904 by a solder joint, for example. A mold compound 928 covers, or at least contacts, the various structures of the semiconductor package 104 of FIGS. 9A-9D.

Each of the openings 916 has a minimum width set to allow for the cutting out of the minimum width of the corresponding downset 926, and the maximum width of each opening 916 is determined by how the opening 916 distorts the radiation pattern of the corresponding antenna 923 and how the opening 916 changes the input impedance of the corresponding antenna 923. The width of each opening 918 is set to tune the impedance of the corresponding antenna 923 and to be narrow enough to result in short and sturdy members 920 that are able to hold that antenna 923 to the member 912. The perimeter of each opening 918 is determined by the size of the corresponding antenna 923, which has a length in the direction of the corresponding downset 926 that is approximately a quarter wavelength at the antenna 923 operating frequency. The width of each antenna 923 tunes the input impedance of that antenna 923 at the operating frequency and the bandwidth of that antenna 923. The length and width of each opening 922 tunes the input impedance and bandwidth of the corresponding antenna 923.

The antenna 923 is a patch antenna, and more specifically, an E-shaped patch antenna. The length of each antenna 923 along the longer side of the package, in line with the corresponding downset 926 determines the resonance frequency of that antenna 923. The feed position affects the impedance of the antenna 923 and the E-shape of the antenna 923 increases the bandwidth of the antenna 923.

The semiconductor die 910 communicates with each of the antennas 923 through a bond wire 911, a package pin 904, and a clip 926. The semiconductor die 910 is configured to simultaneously operate the antennas 923. For example, the semiconductor die 910 may transmit and receive wireless signals using the antennas 923 on different frequencies that are adequately separated from each other to avoid interference between the wireless signals.

In some examples, the antennas 923 may be oriented differently than in FIGS. 9A-9D for various reasons. For example, different orientations may facilitate radiation patterns directed in specific directions, or advantageous package layouts. FIG. 9E is a perspective view of an example semiconductor package 104 including a package antenna in accordance with various examples. At least some of the antennas 923 in FIG. 9E contact members 932, which, in turn, contact clips 926. Each of the members 932 includes a right-angle turn, as shown, to facilitate extension of the corresponding clip 926 toward the package pin 904 to which that clip 926 is to be coupled.

FIG. 10 is a graph 1000 depicting the performance of a semiconductor package (e.g., the semiconductor package 104 of FIGS. 9A-9D) including a package antenna (e.g., the antennas 923), in accordance with various examples. The graph 1000 depicts Theta in degrees on the x-axis, and gain in decibels relative to isotropic (dBi) on the y-axis. The graph 1000 includes four pairs of curves. Each pair of curves depicts the radiation pattern produced by one of the antennas 923, and because the example semiconductor package 104 includes four antennas 923, there are four such pairs of curves in the graph 1000. In each pair of curves characterizing the radiation pattern provided by a given antenna 923, the first curve depicts performance at 60 GHz in the plane that extends through the antenna’s maximum radiation direction (i.e., Phi = 0 degrees), and the second curve depicts performance at 60 GHz in the plane that is perpendicular to that of the first curve (i.e., Phi = 90 degrees). As shown, the antennas 923 provide radiation patterns that are comparable to each other.

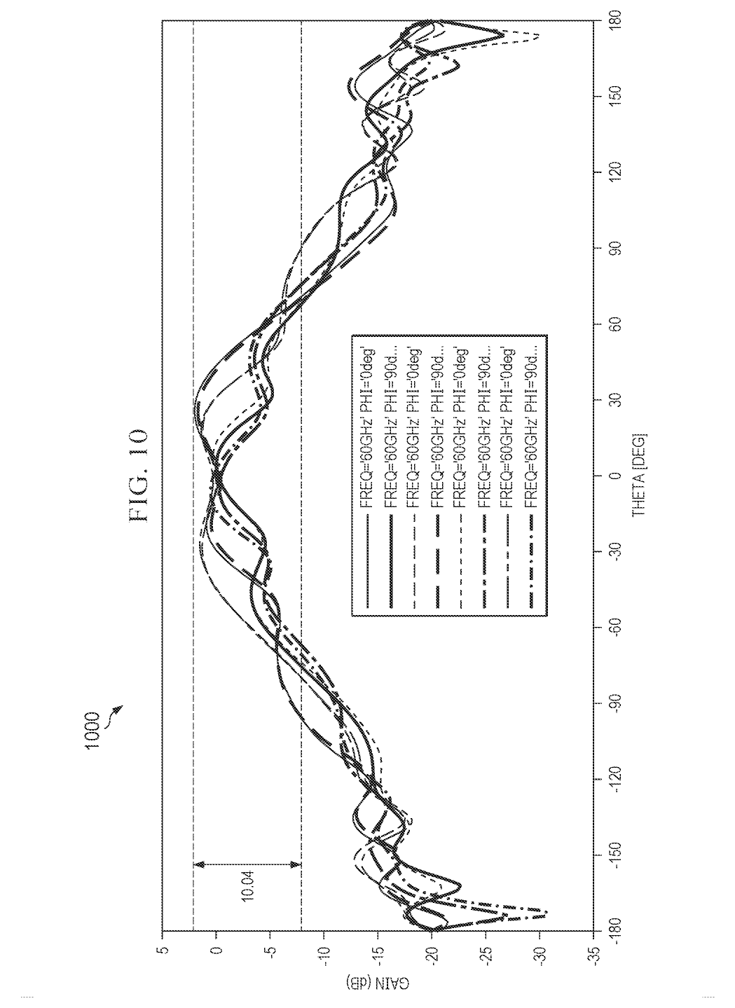

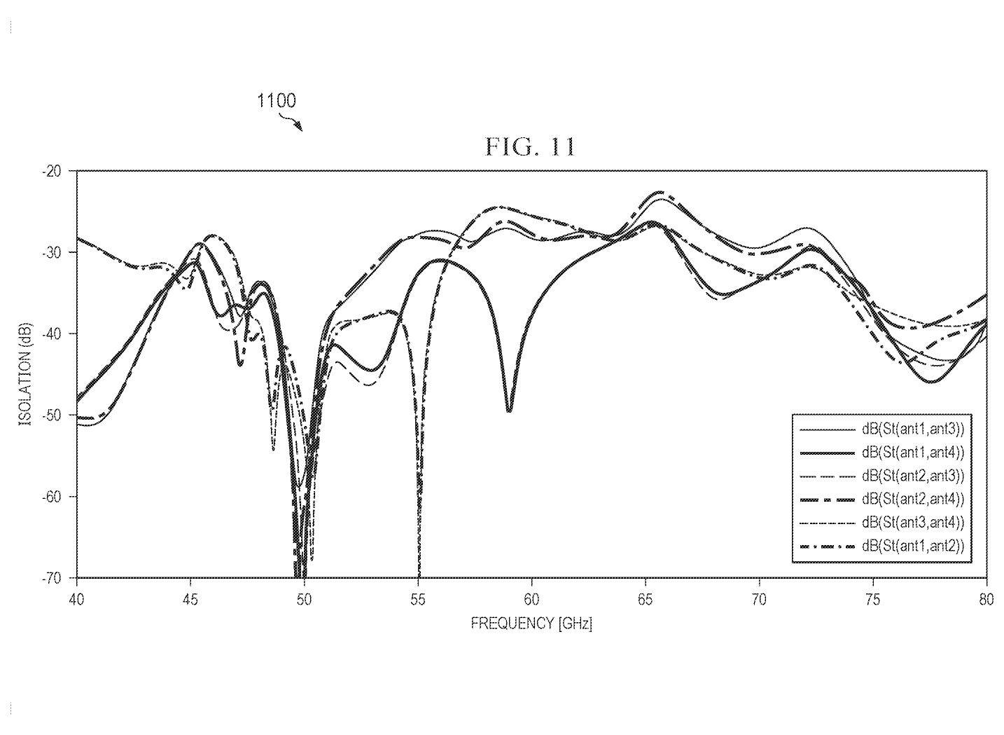

FIG. 11 is a graph 1100 depicting the performance of a semiconductor package including a package antenna, in accordance with various examples. More particularly, the graph 1100 depicts the isolation achieved by each antenna 923 relative to the other antennas 923. The graph 1100 includes frequency in GHz on the x-axis, and isolation in dB on the y-axis. The graph 1100 further includes six curves, with each curve representing the isolation performance between a different pair of antennas (i.e., a first antenna with a second antenna, the first antenna with a third antenna, the first antenna with a fourth antenna, the second antenna with the third antenna, the second antenna with the fourth antenna, and the third antenna with the fourth antenna). The graph 1100 indicates that each of the antennas 923 maintains adequate isolation, generally in the -30 dB to -40 dB range. The curves include multiple dips, which extend as low as -50 dB to -70 dB, indicating that in specific frequency bands, the antenna isolation is stronger.

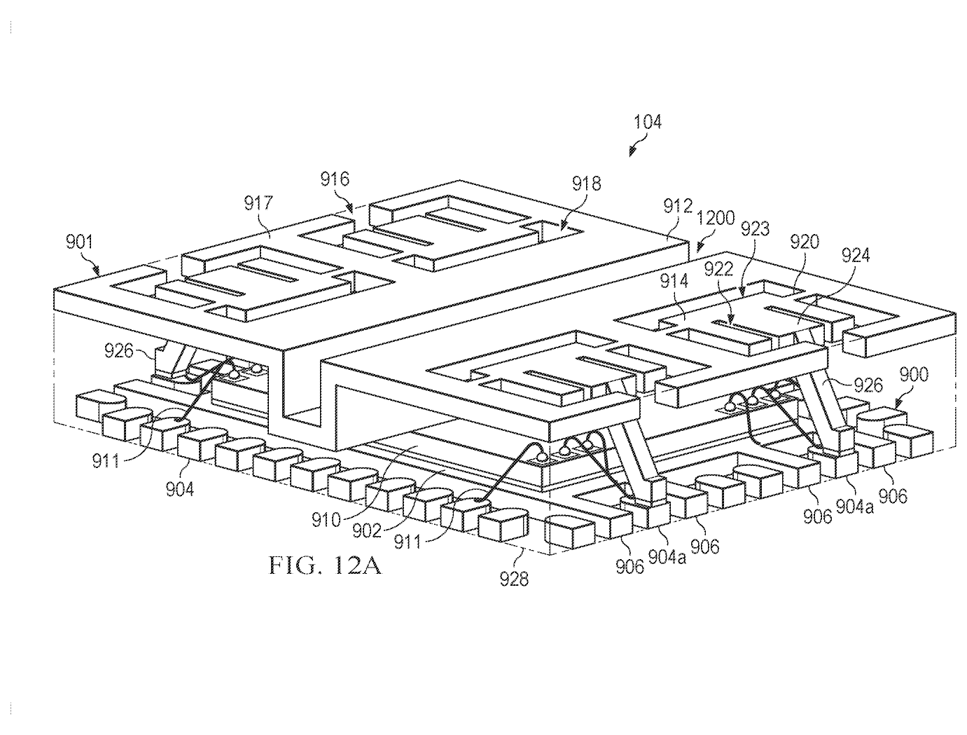

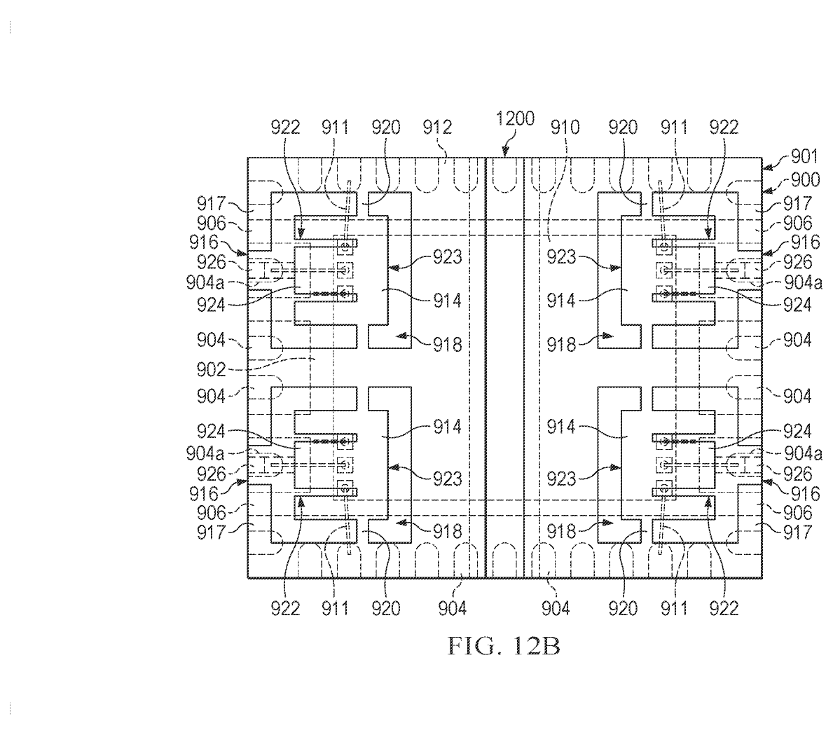

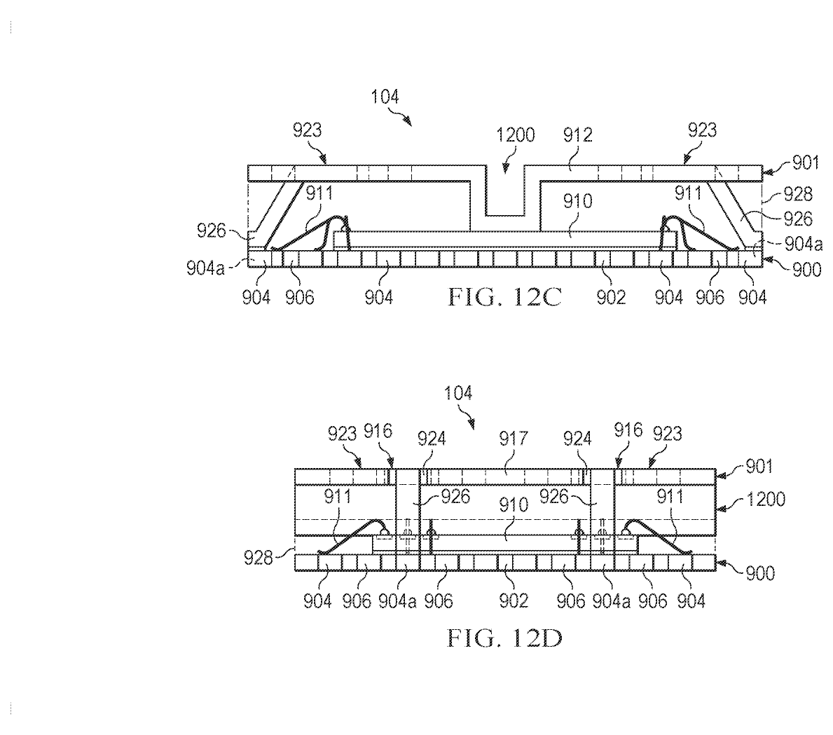

FIGS. 12A, 12B, 12C, and 12D are perspective, top-down, profile, and profile views of a semiconductor package including a package antenna, in accordance with various examples. The structure of FIGS. 12A-12D is identical to that in FIGS. 9A-9D, except that the member 912 includes a cavity 1200 that mitigates interference and enhances isolation between antennas on opposing sides of the cavity 1200. The dimensions of the cavity 1200 are selected to enable such interference mitigation and isolation.

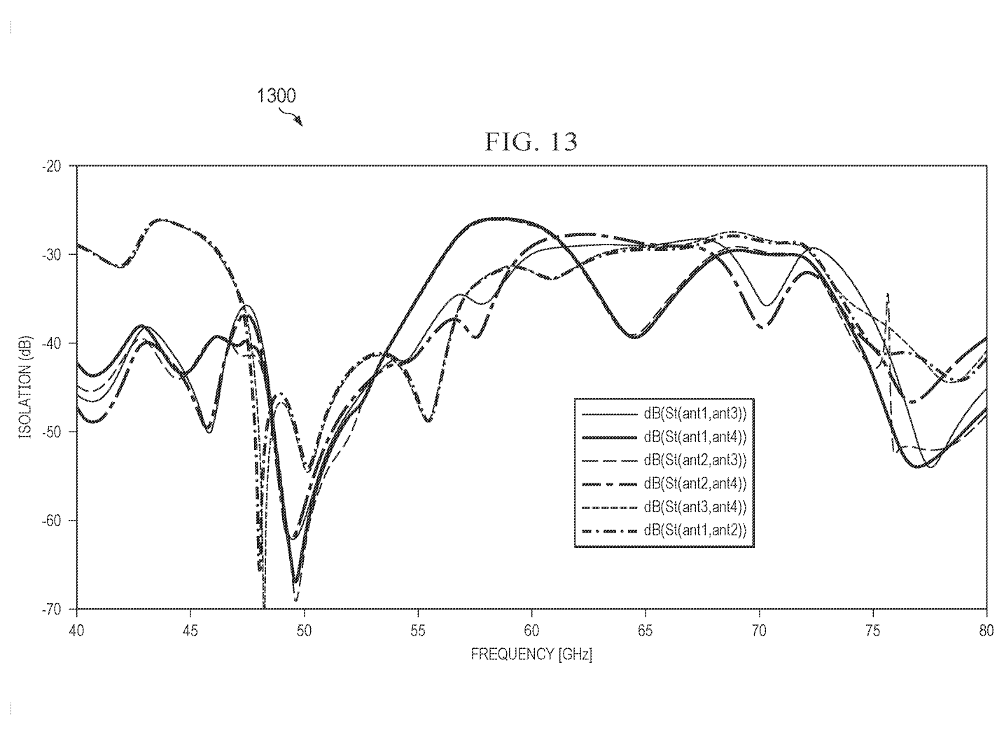

FIG. 13 is a graph 1300 depicting the performance of a semiconductor package including a package antenna, in accordance with various examples. The graph 1300 shows that by introducing the cavity 1200 (i.e., vertical walls), isolation is improved between antennas 923. The lower the value on the y-axis, the less the crosstalk between antennas 923 and the better the isolation performance of the device.

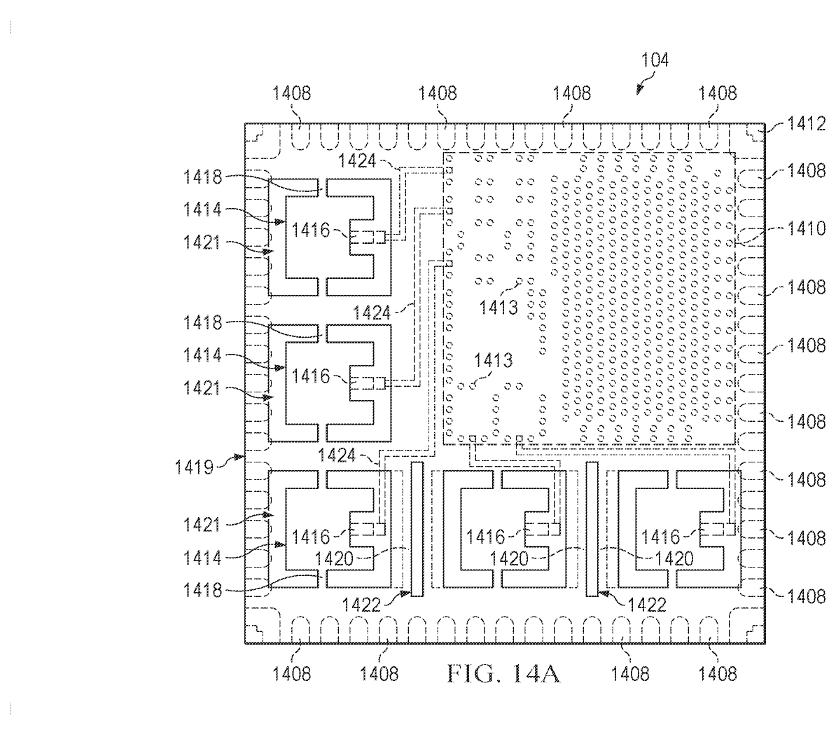

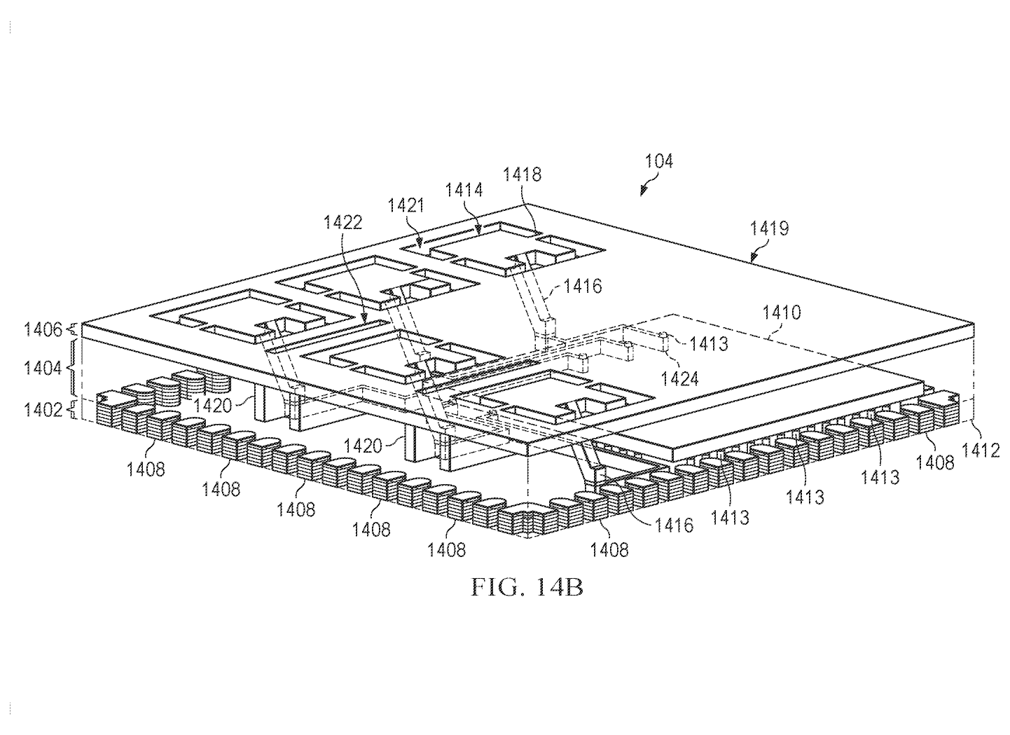

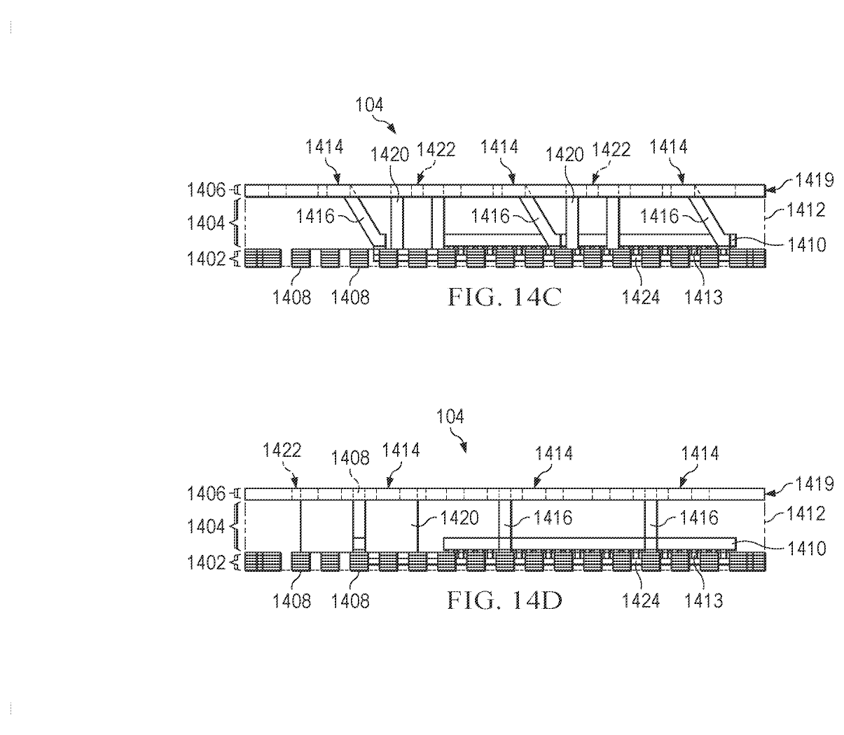

Packages having multi-layer substrates are also contemplated. FIGS. 14A, 14B, 14C, and 14D are top-down, perspective, profile, and profile views of a semiconductor package 104 including a package antenna, in accordance with various examples. The example semiconductor package 104 of FIGS. 14A-14D includes a multi-layer substrate 1402, an intermediate layer 1404, and an antenna layer 1406. The multi-layer substrate 1402 (e.g., ball grid array, embedded trace substrate) includes multiple metal layers (e.g., metal traces and/or vias) and multiple non-air dielectric layers (e.g., AJINOMOTO® build-up film (ABF) or pre-preg) contacting the multiple metal layers (e.g., positioned between at least some of the metal layers). The multi-layer substrate 1402 also includes package pins 1408. The metal layers of the multi-layer substrate 1402 extend from a top surface of the multi-layer substrate 1402 to the package pins 1408. The intermediate layer 1404 includes a semiconductor die 1410 that is coupled to the metal layers of the multi-layer substrate 1402 by metal connectors (e.g., copper posts, pillars, solder joints) 1413. The intermediate layer 1404 also includes a mold compound 1412. The antenna layer 1406 includes multiple antennas 1414 (e.g., patch antennas) coupled by members 1418 (e.g., tie bars) to a frame 1419. The antennas 1414 are suspended in openings 1421 by the members 1418. The antennas 1414 are coupled to the top surface of the multi-layer substrate 1402 (i.e., to the metal layers of the multi-layer substrate 1402) by the clips 1416. More specifically, the metal layers in the multi-layer substrate 1402 include metal traces 1424, which couple the clips 1416 to the semiconductor die 1410. The frame 1419 includes, between some antenna 1414 pairs, protrusions 1420 and an opening 1422 between the protrusions 1420. The protrusions 1420 extend from the frame 1419 downward, toward the multi-layer substrate 1402. The protrusions 1420 and the opening 1422 increase isolation between adjacent antennas 1414.

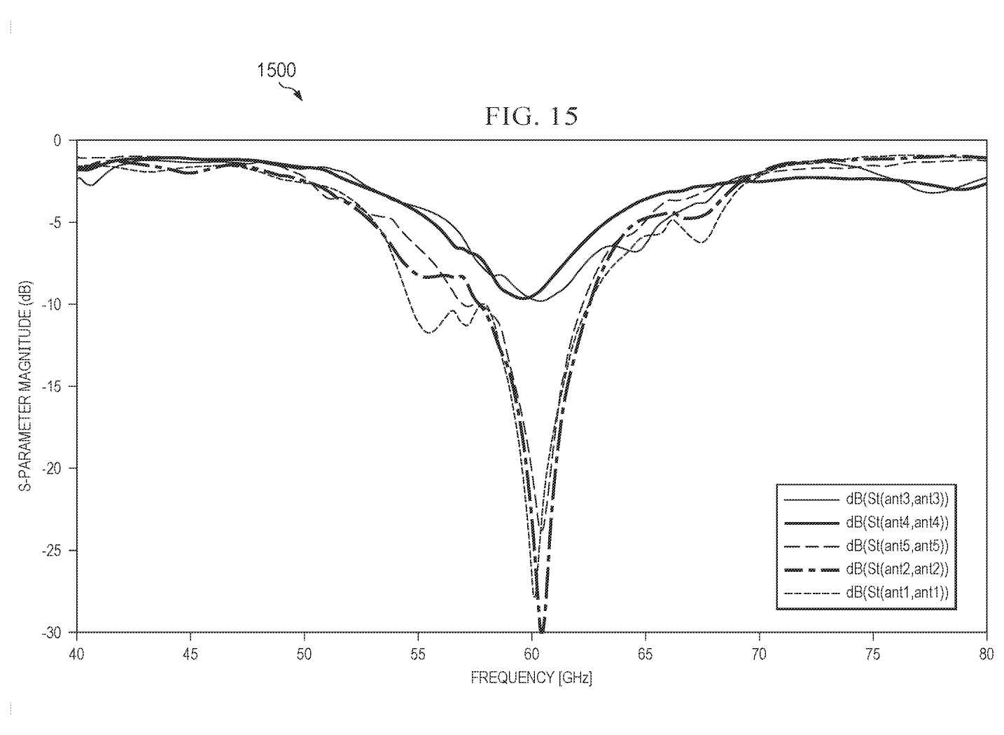

FIG. 15 is a graph 1500 depicting the performance of a semiconductor package including a package antenna, in accordance with various examples. More particularly, the graph 1500 depicts the return loss associated with each of the five antennas of the semiconductor package 104 of FIGS. 14A-14D. The graph 1500 includes frequency in GHz on the x-axis and S-parameter magnitude in dB on the y-axis. Each of the curves in the graph 1500 corresponds to a different antenna 1414 in the semiconductor package 104 of FIGS. 14A-14D. Each of the antennas is well-matched to a respective feeding line at approximately 60 GHz.

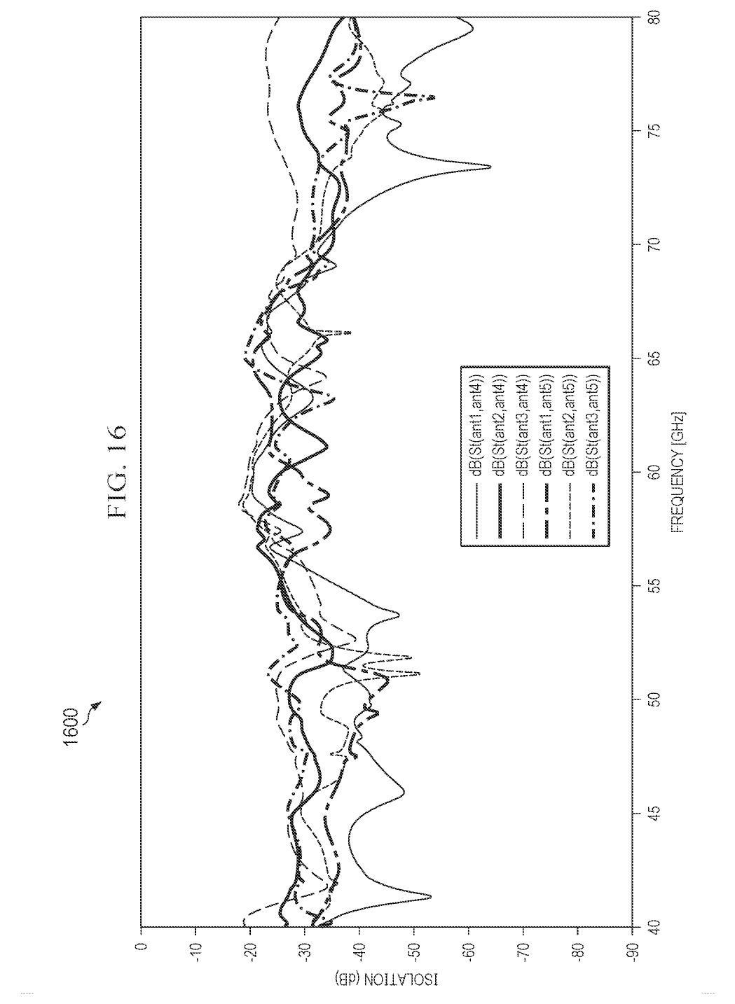

FIG. 16 is a graph 1600 depicting the performance of a semiconductor package including a package antenna, in accordance with various examples. More particularly, the graph 1600 depicts the isolation (in dB) present between different antenna pairs as a function of frequency (in GHz). The graph 1600 demonstrates substantial isolation between the antenna pairs for each of the curves, with no significant isolation dips that would indicate suboptimal performance.

FIG. 17 is a graph 1700 depicting the performance of a semiconductor package (e.g., the semiconductor package 104 of FIGS. 14A-14D) including a package antenna (e.g., the antennas 1414), in accordance with various examples. The graph 1700 depicts Theta in degrees on the x-axis, and gain in decibels relative to isotropic (dBi) on the y-axis. The graph 1700 includes five pairs of curves. Each pair of curves depicts the radiation pattern produced by one of the antennas 1414, and because the example semiconductor package 104 includes five antennas 1414, there are five such pairs of curves in the graph 1700. In each pair of curves characterizing the radiation pattern provided by a given antenna 1414, a first curve depicts performance at 60 GHz in the plane that extends through the antenna’s maximum radiation direction (i.e., Phi = 0 degrees), and a second curve depicts performance at 60 GHz in the plane that is perpendicular to that of the first curve (i.e., Phi = 90 degrees). As shown, the antennas 1414 provide radiation patterns that are comparable to each other.

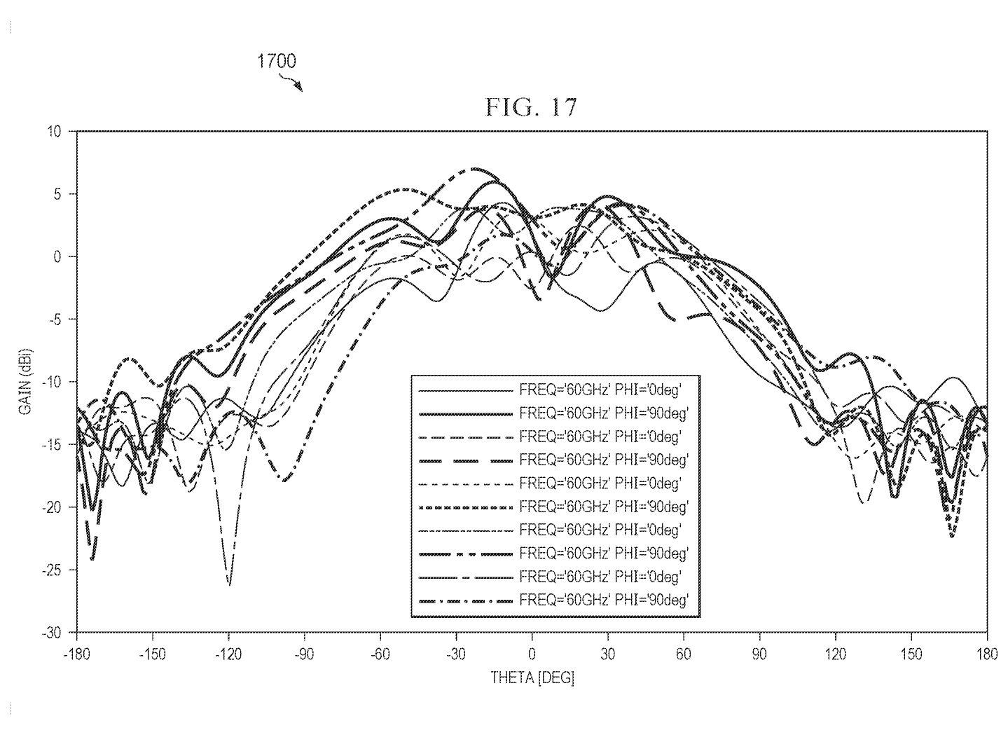

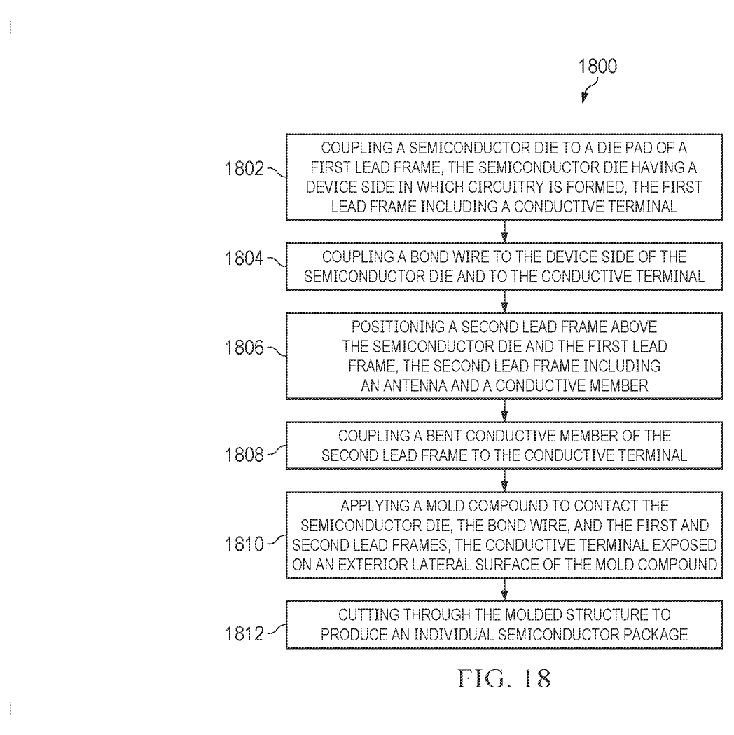

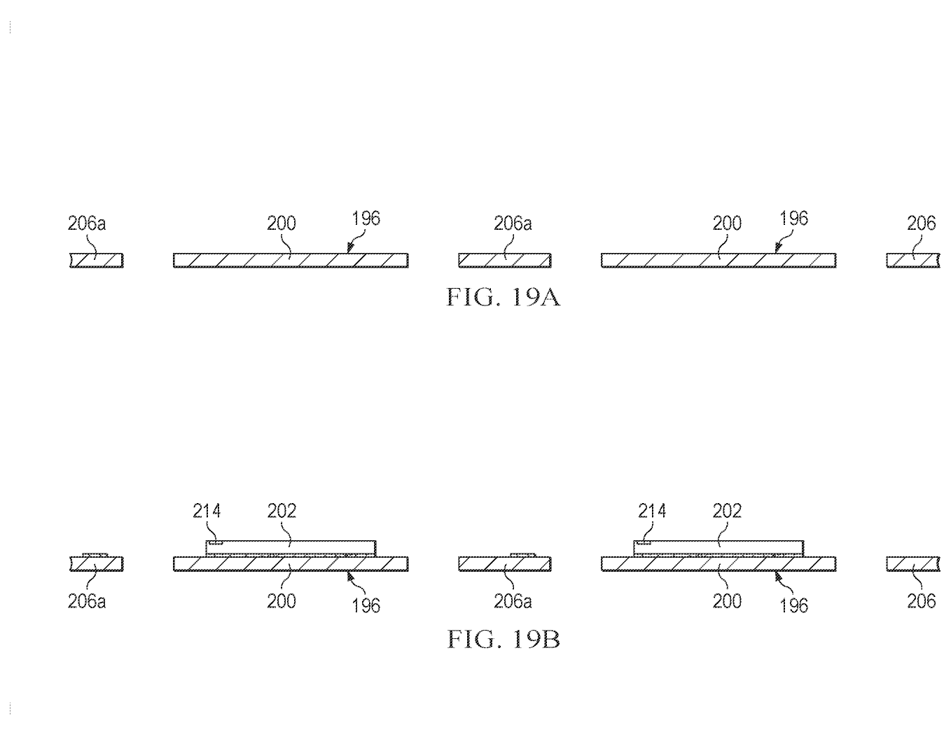

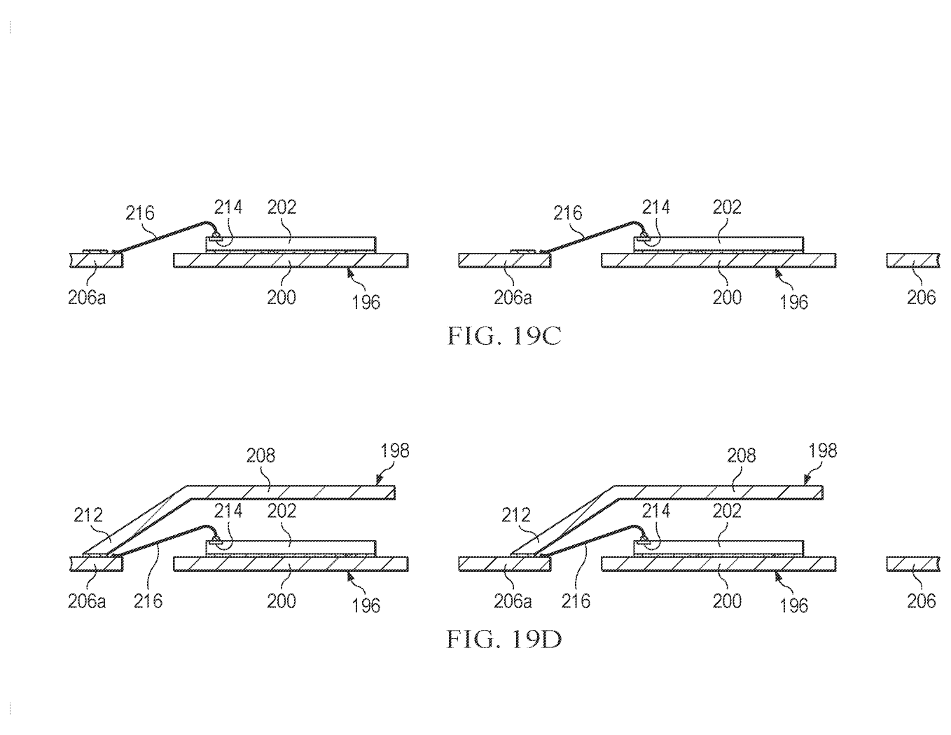

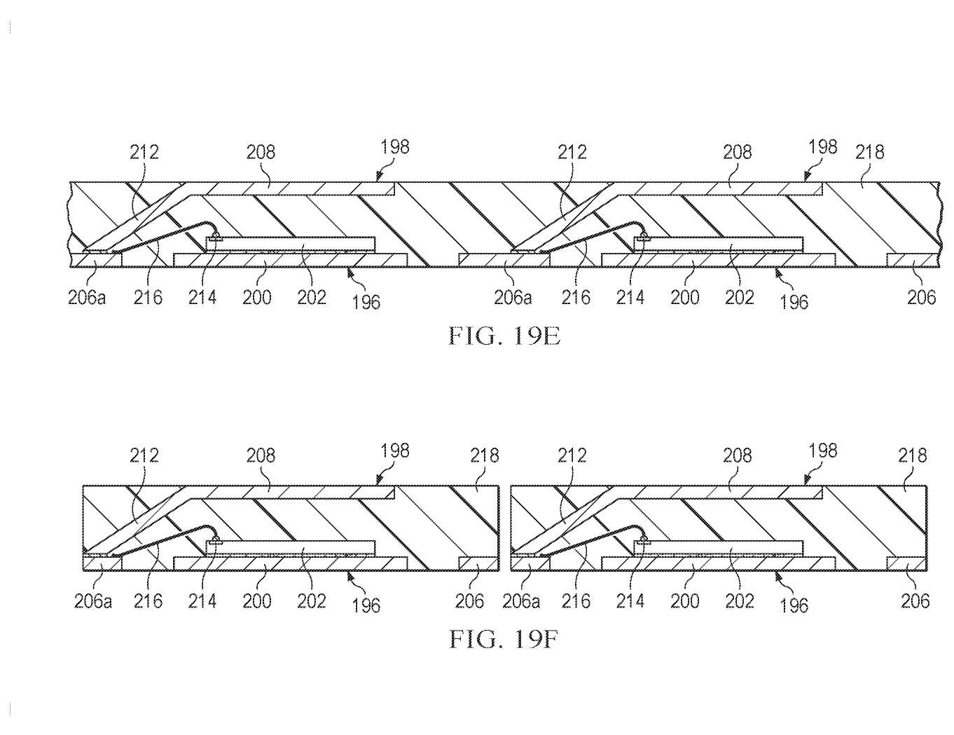

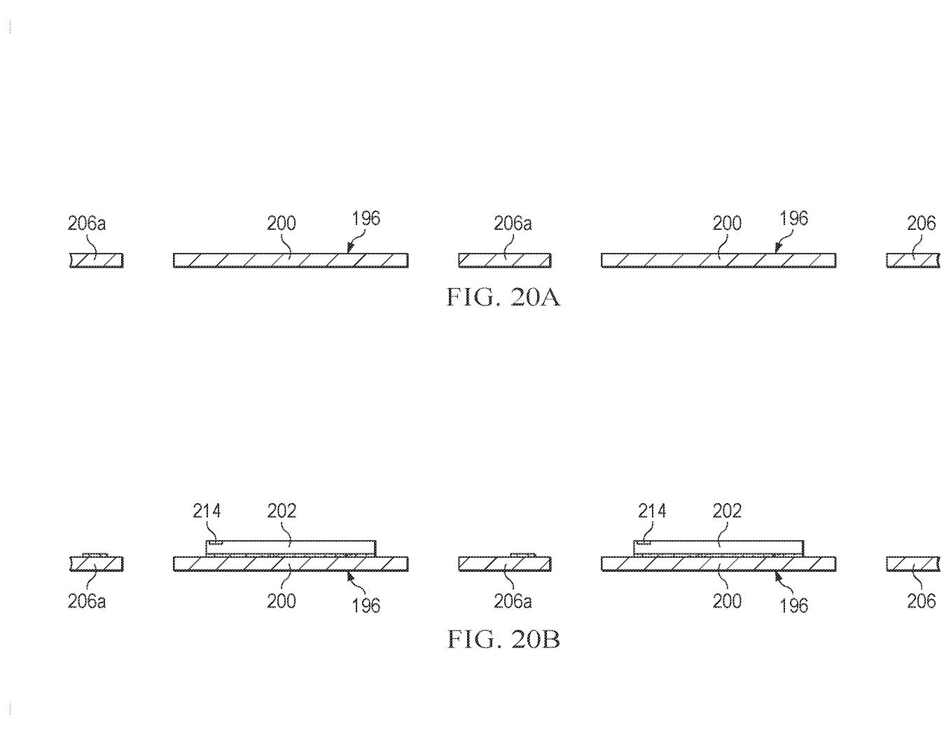

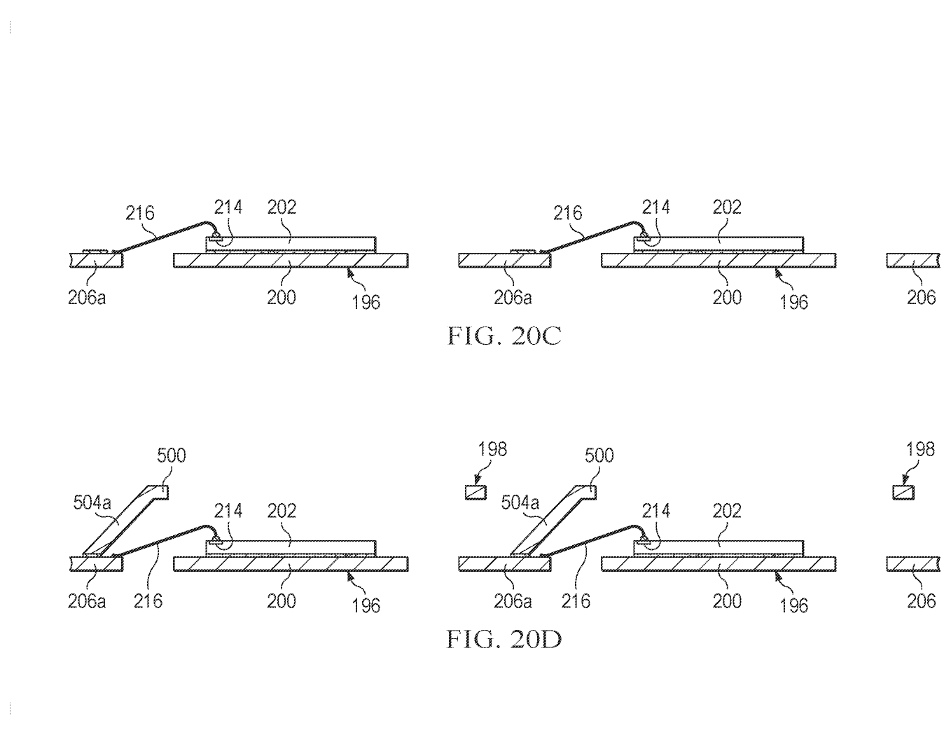

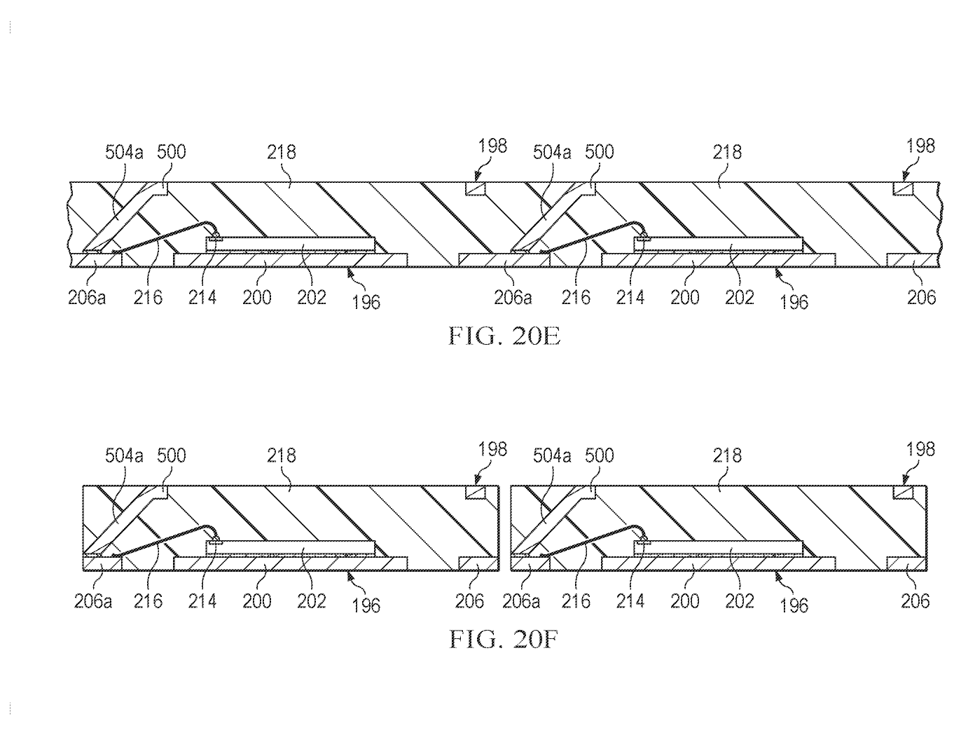

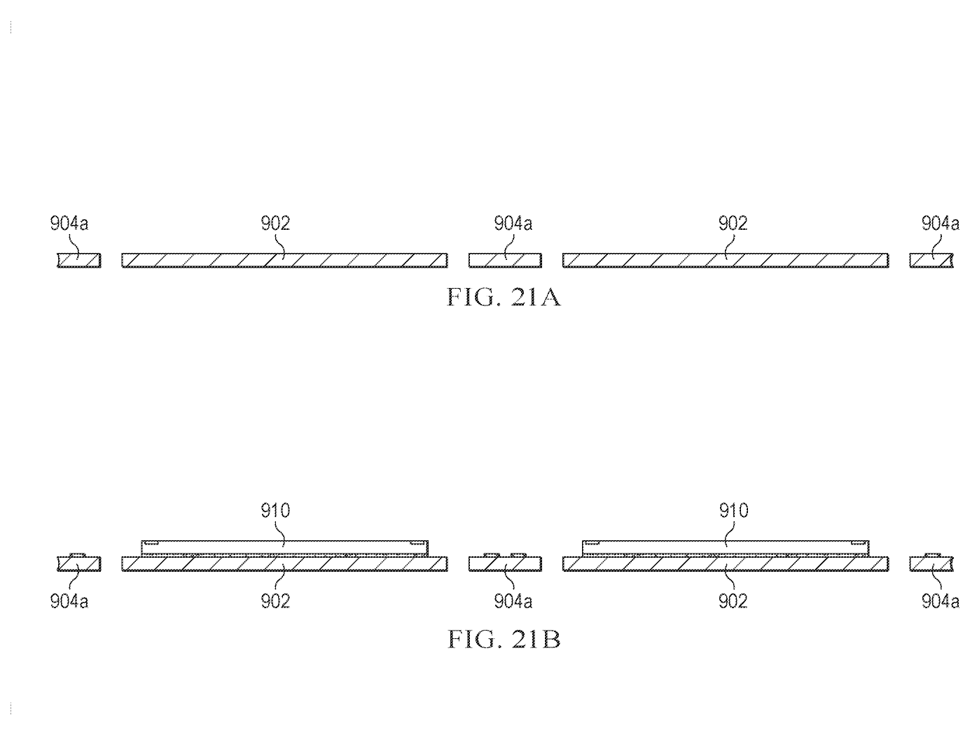

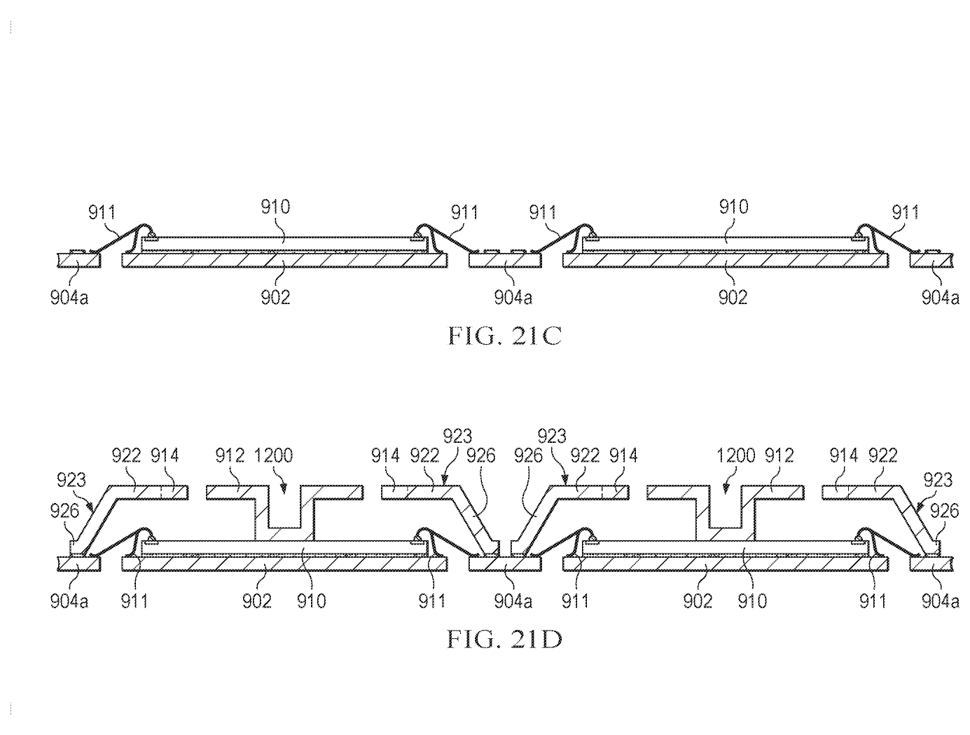

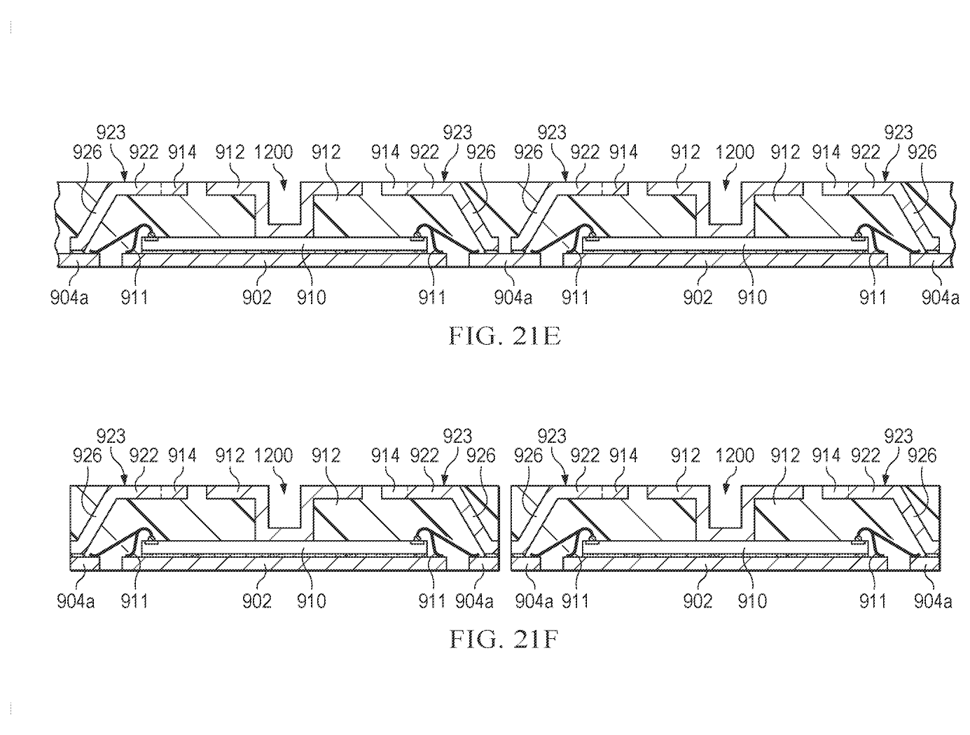

FIG. 18 is a flow diagram of a method 1800 for manufacturing a semiconductor package including a package antenna (e.g., the semiconductor packages 104 of FIGS. 2A-2D, 5A-5D, and 12A-12D), in accordance with various examples. FIGS. 19A-19F are a process flow of the method 1800 for manufacturing a semiconductor package including a package antenna, such as the semiconductor package 104 of FIGS. 2A-2D. FIGS. 20A-20F are a process flow of the method 1800 for manufacturing a semiconductor package including a package antenna, such as the semiconductor package 104 of FIGS. 5A-5D. FIGS. 21A-21F are a process flow of the method 1800 for manufacturing a semiconductor package including a package antenna, such as the semiconductor package 104 of FIGS. 9A-9D. Accordingly, FIGS. 18, 19A-19F, 20A-20F, and 21A-21F are now described in parallel.

The method 1800 includes coupling a semiconductor die to a die pad of a first lead frame (1802). The semiconductor die has a device side in which circuitry is formed (1802). The first lead frame includes a conductive terminal (i.e., a package pin) (1802). FIG. 19A depicts a lead frame strip that includes die pads 200 and package pins 206. FIG. 19B depicts the structure of FIG. 19A, except that semiconductor dies 202 are coupled to respective die pads 200 (e.g., using die attach material). The semiconductor dies 202 have device sides in which circuitry is formed. The device sides of the semiconductor dies 202 face upward, away from the die pads 200.

The method 1800 includes coupling a bond wire to the device side of the semiconductor die and to the conductive terminal (1804). FIG. 19C depicts the structure of FIG. 19B, except that bond wires 216 are coupled to the device sides of the semiconductor dies 202 and to the package pins 206.

The method 1800 includes positioning a second lead frame above the semiconductor die and the first lead frame, where the second lead frame includes an antenna and a conductive member (1806), and coupling a bent conductive member of the second lead frame to the conductive terminal (1808). The conductive member may be bent during lead frame manufacture, during performance of the method 1800, or at any time therebetween. FIG. 19D depicts the structure of FIG. 19C, except that a second lead frame strip is positioned over the first lead frame strip, and the clips 212 are coupled to respective package pins 206 (e.g., by solder joints), as shown. The second lead frame strip includes multiple antennas 208 and multiple clips 212.

The method 1800 includes applying a mold compound to physically contact the semiconductor die, the bond wire, and the first and second lead frames (1810). The conductive terminal is exposed on an exterior lateral surface of the mold compound (1810). FIG. 19E depicts the structure of FIG. 19D, except that the mold compound 218 is applied to both the lead frame strips, as shown. The method 1800 includes cutting (e.g., sawing) through the molded structure to produce an individual semiconductor package (1812). FIG. 19F depicts the structure of FIG. 19E, except that the molded structure of FIG. 19E has been singulated into individual semiconductor packages (e.g., semiconductor packages 104).

As described above, the method 1800 is useful to manufacture the semiconductor package 104 of FIGS. 5A-5D. As FIGS. 20A and 20B show, the step 1802 is useful to couple semiconductor dies 202 to die pads 200 of a first lead frame strip, where the semiconductor dies 202 have device sides in which circuitry is formed, and the first lead frame strip includes package pins 206. The semiconductor dies 202 may be coupled to the die pads 200 by suitable die attach material.

The method 1800 includes coupling a bond wire to the device side of the semiconductor die and to the conductive terminal (1804). FIG. 20C depicts the structure of FIG. 20B, except that bond wires 216 are coupled to the semiconductor dies 202 and to the package pins 206.

The method 1800 includes positioning a second lead frame strip above the semiconductor die and the first lead frame strip, with the second lead frame strip including an antenna and a conductive member (i.e., clips) (1806). The method 1800 also includes coupling a bent conductive member to the conductive terminal (1808). The conductive member may be bent during lead frame manufacture, during performance of the method 1800, or at any time therebetween. FIG. 20D depicts the structure of FIG. 20C, except that a second lead frame strip including antennas 500 coupled to each other by tie bars 502 (FIG. 5A) is positioned above the first lead frame strip, and the bent conductive members (e.g., clips 504a, 504b, FIG. 5A) are coupled to the respective conductive terminals (e.g., package pins 206a, 206b).

The method 1800 includes applying a mold compound to contact the semiconductor die, the bond wire, and the first and second lead frames, with the conductive terminal exposed on an exterior lateral surface of the mold compound (1810). FIG. 20E depicts the structure of FIG. 20D, except that a mold compound 218 is applied. The method 1800 includes cutting through the molded structure to produce an individual semiconductor package (1812). FIG. 20F depicts the structure of FIG. 20E, except that the molded structure has been sawn to produce individual semiconductor packages 104, as shown.

As described above, the method 1800 is useful to manufacture the semiconductor package 104 of FIGS. 12A-12D. As FIGS. 21A and 21B show, the step 1802 is useful to couple semiconductor dies 910 to die pads 902 of a first lead frame strip, where the semiconductor dies 910 have device sides in which circuitry is formed, and the first lead frame strip includes package pins 904 (FIGS. 9A-9E). The semiconductor dies 910 may be coupled to the die pads 902 by suitable die attach material.

The method 1800 includes coupling a bond wire to the device side of the semiconductor die and to the conductive terminal (1804). FIG. 21C depicts the structure of FIG. 21B, except that bond wires 911 are coupled to the semiconductor dies 910 and to the package pins 904.

The method 1800 includes positioning a second lead frame strip above the semiconductor die and the first lead frame strip, with the second lead frame strip including an antenna and a conductive member (i.e., clips) (1806), and coupling a bent conductive member to the conductive terminal (1808). The conductive member may be bent during lead frame manufacture, during performance of the method 1800, or at any time therebetween. FIG. 21D depicts the structure of FIG. 21C, except that a second lead frame strip including antennas 923 coupled to members 912 by members 920 (FIG. 9A-9E) is positioned above the first lead frame strip, and the bent conductive members (e.g., clips 926) are coupled to the respective conductive terminals (e.g., package pins 904a).

The method 1800 includes applying a mold compound to contact the semiconductor die, the bond wire, and the first and second lead frames, with the conductive terminal exposed on an exterior lateral surface of the mold compound (1810). FIG. 21E depicts the structure of FIG. 21D, except that a mold compound 928 is applied. The method 1800 includes cutting through the molded structure to produce an individual semiconductor package (1812). FIG. 21F depicts the structure of FIG. 21E, except that the molded structure has been sawn to produce individual semiconductor packages 104, as shown.

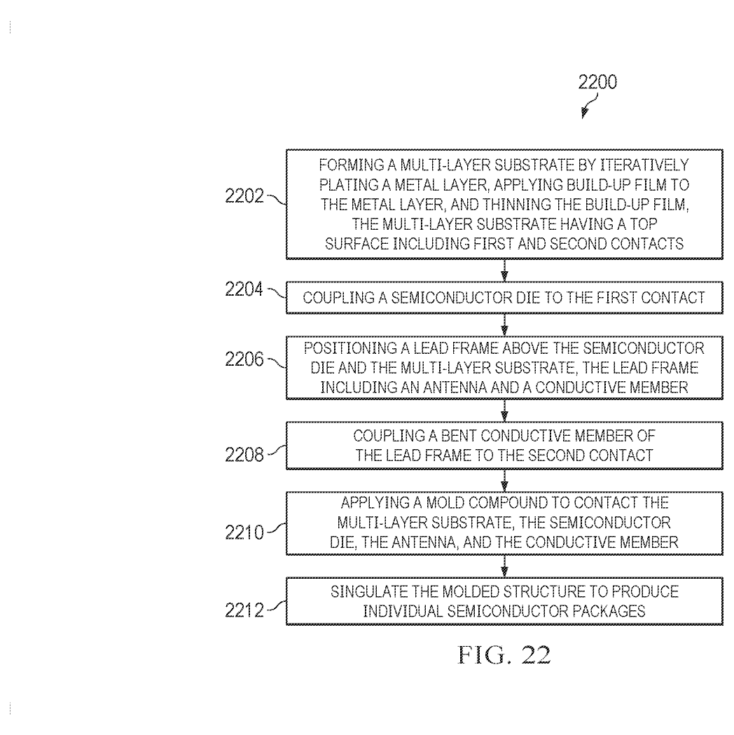

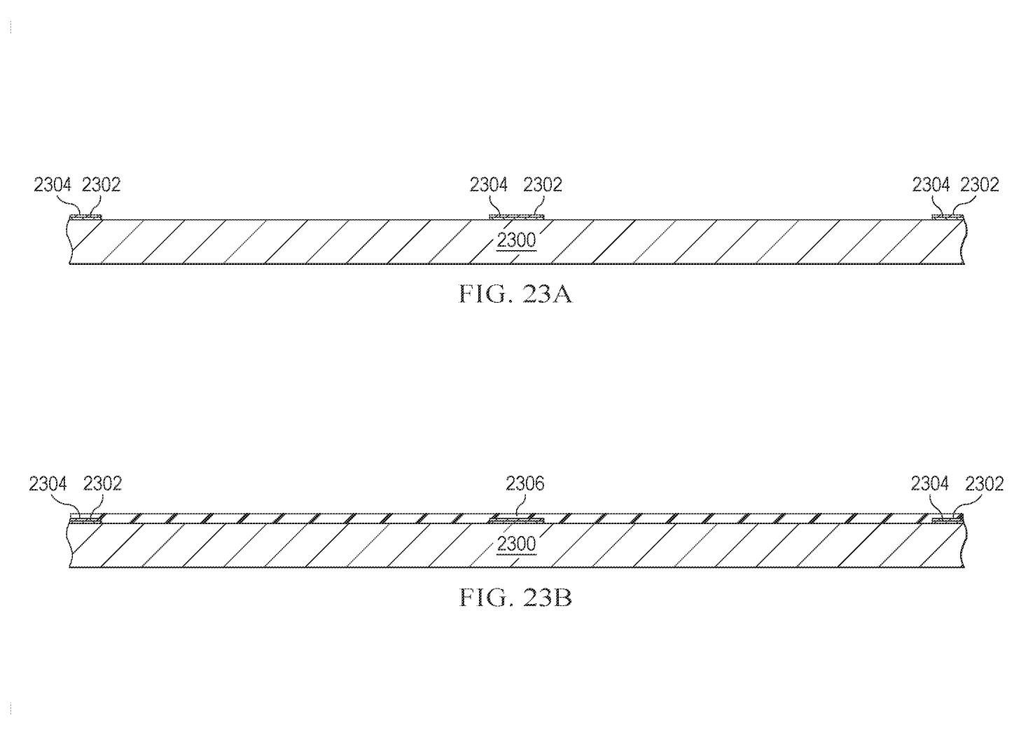

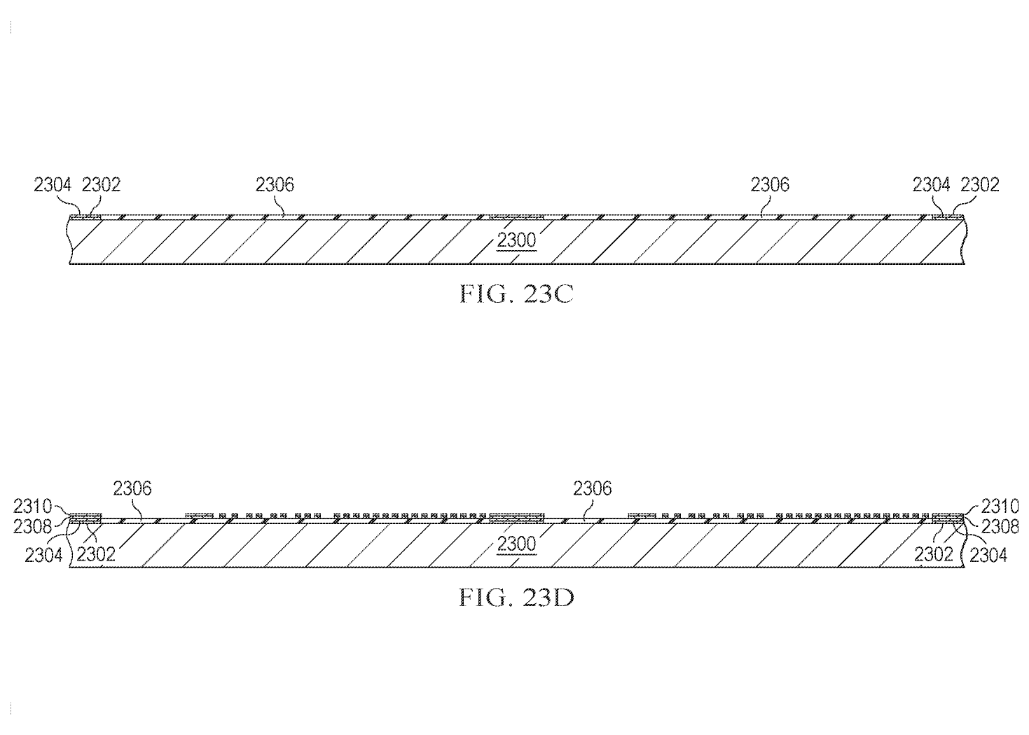

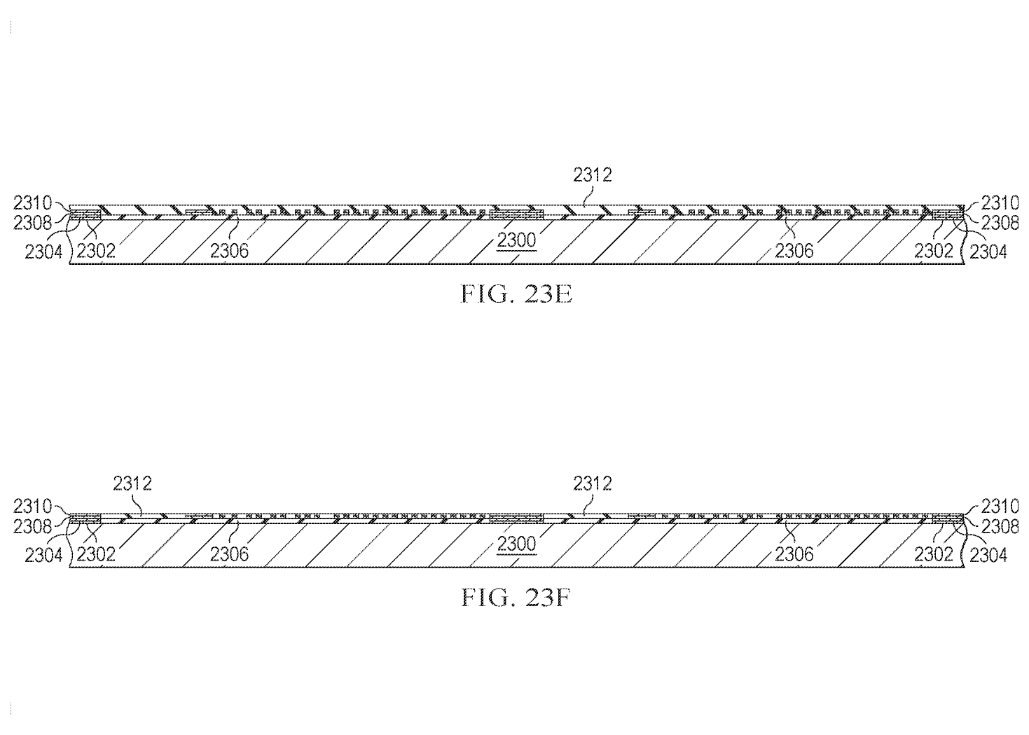

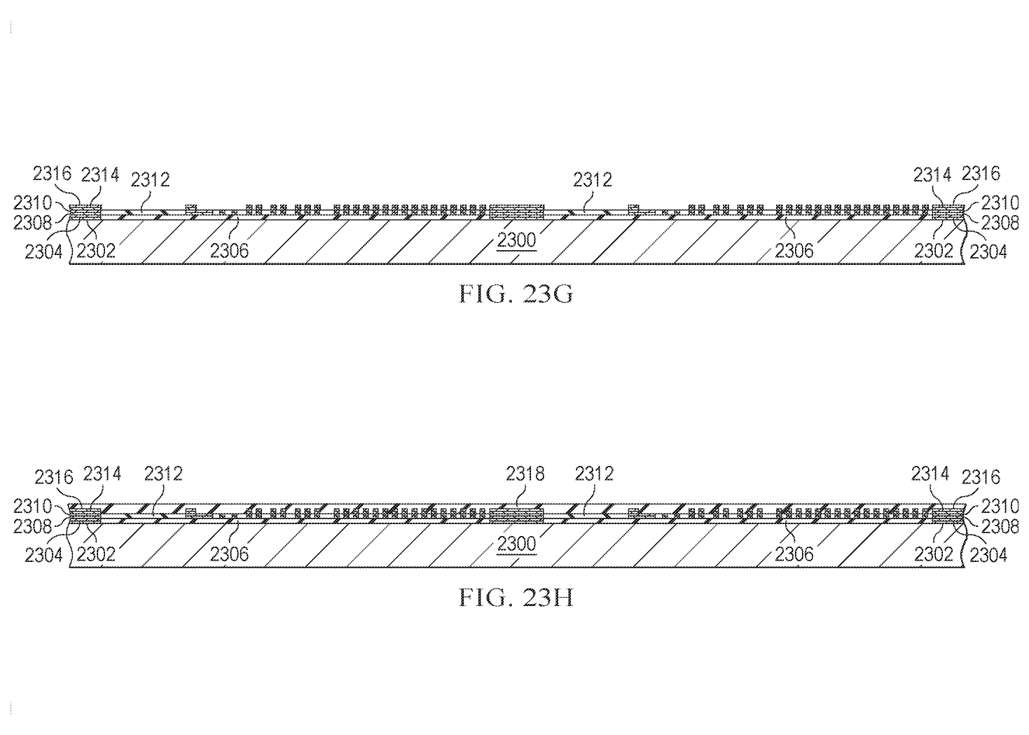

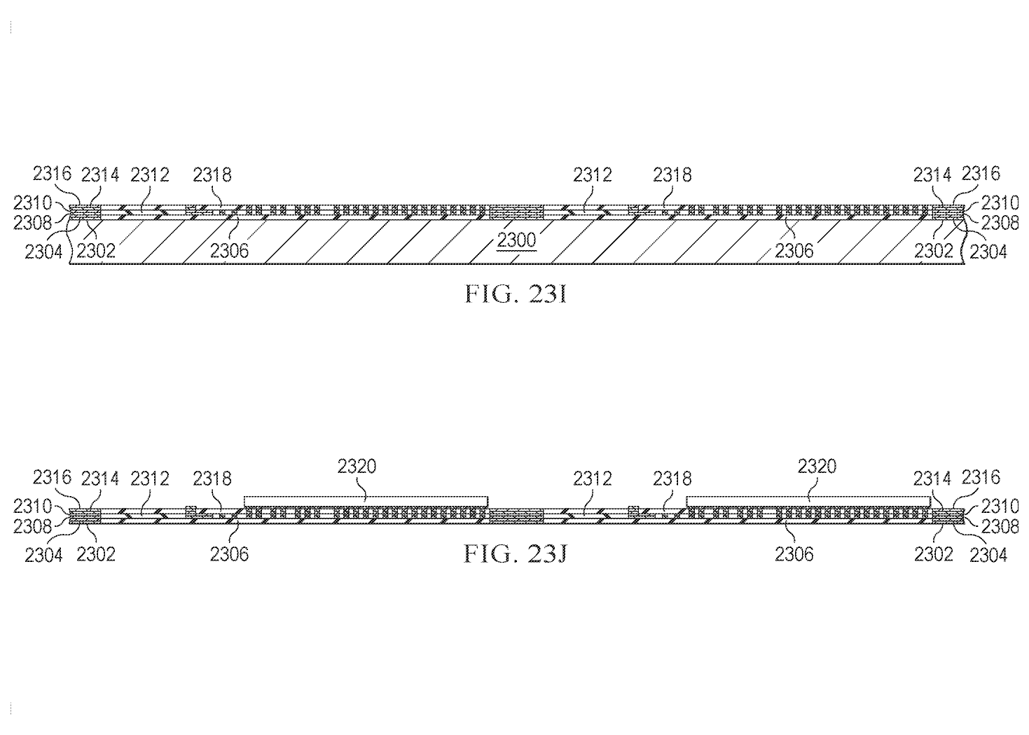

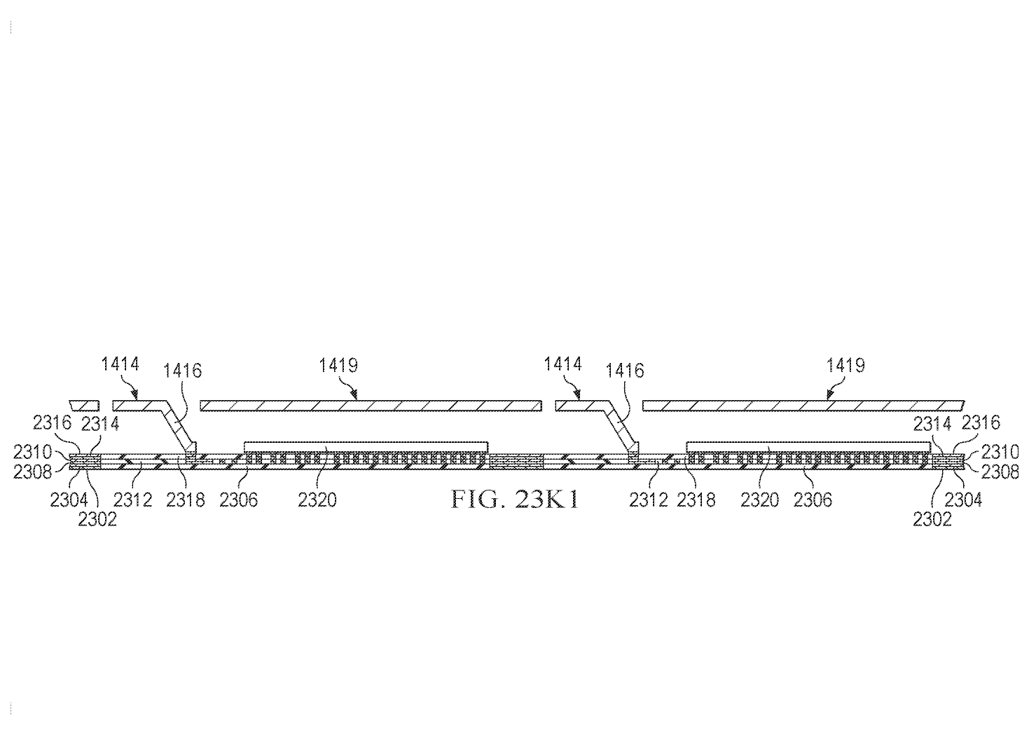

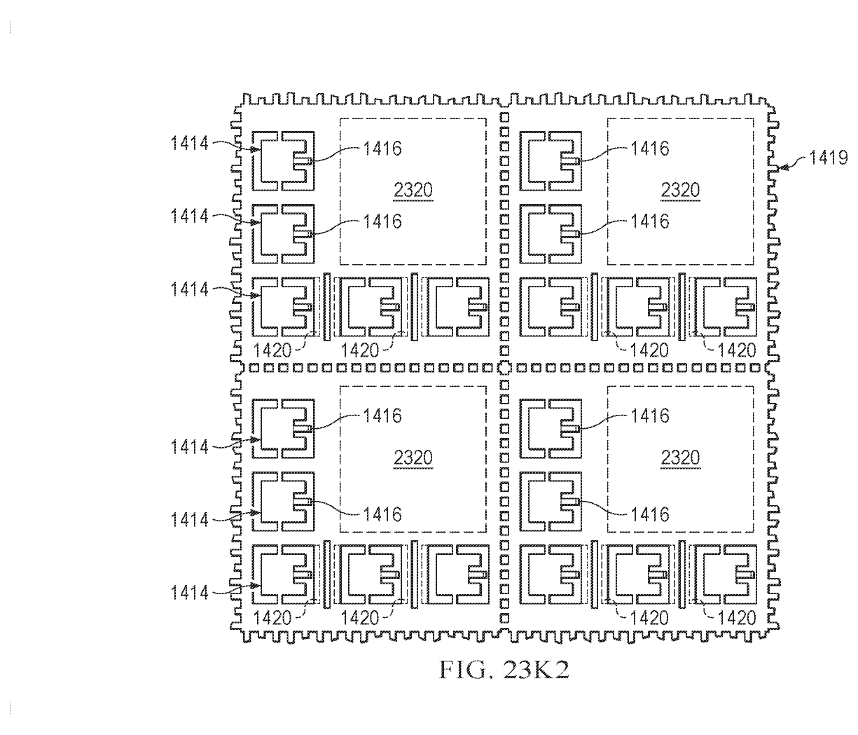

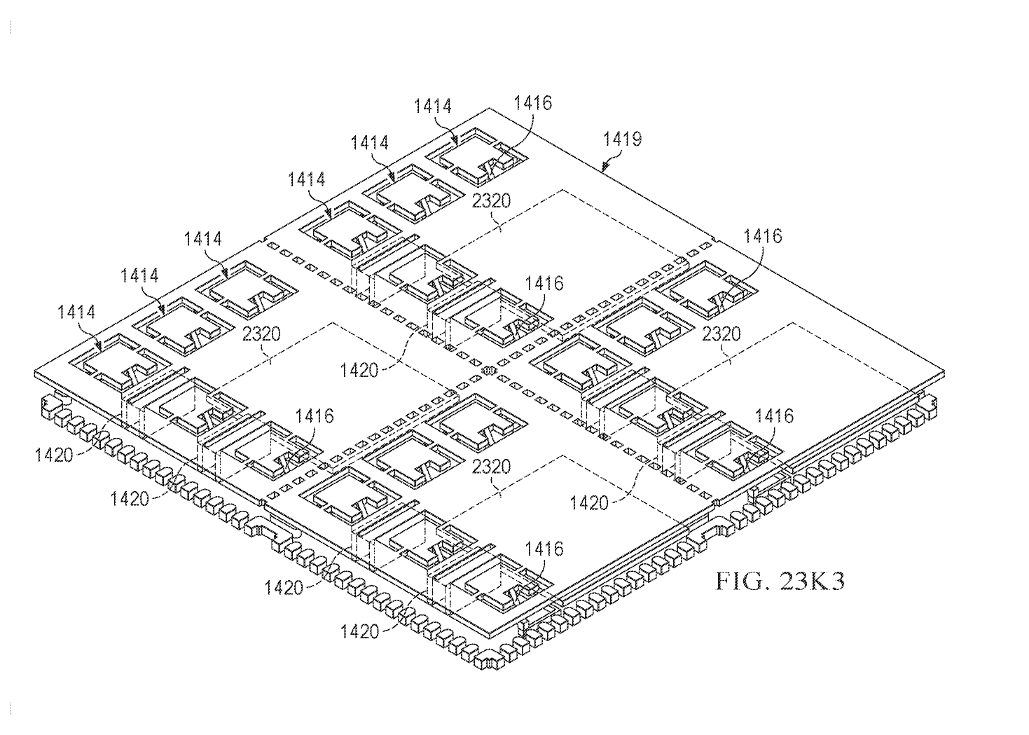

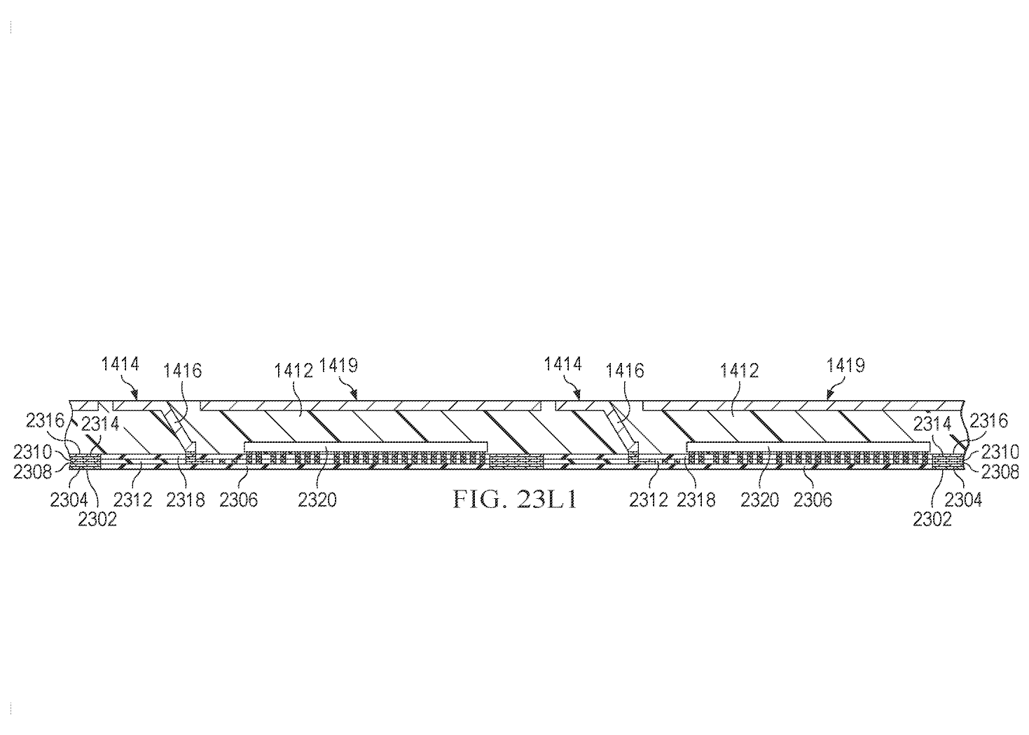

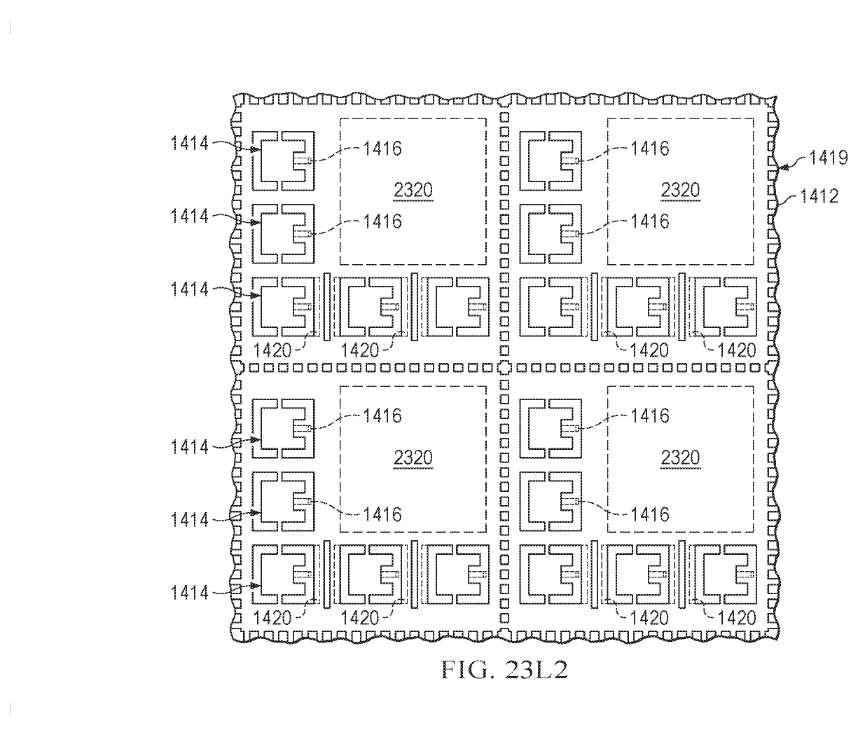

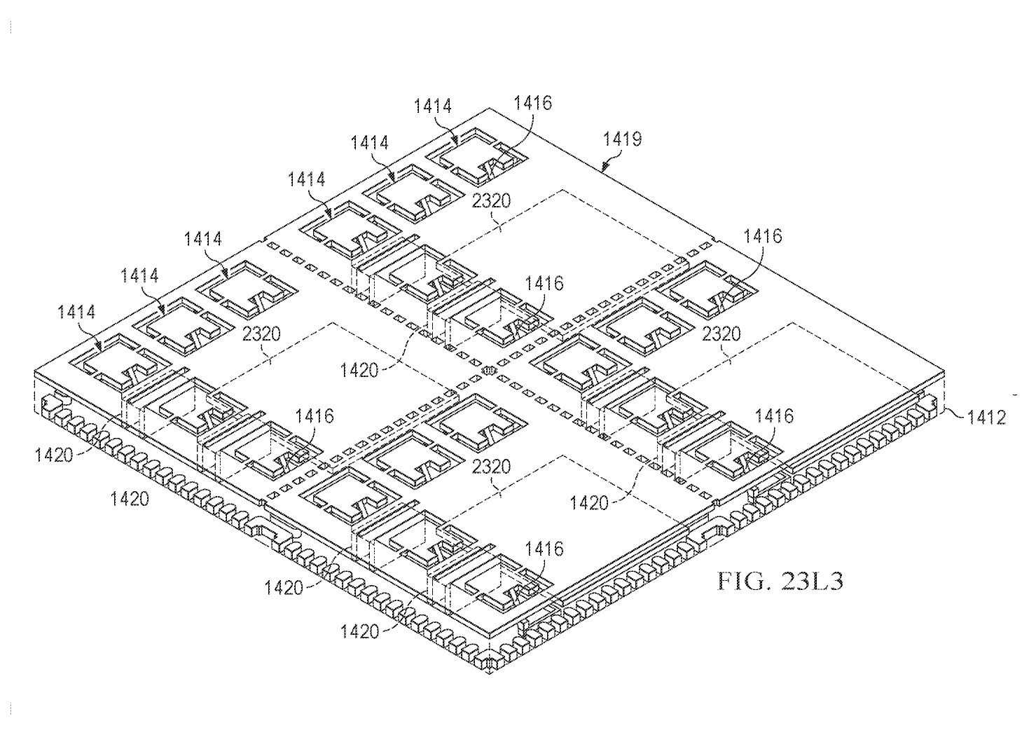

FIG. 22 is a flow diagram of a method 2200 for manufacturing a semiconductor package including a package antenna, in accordance with various examples. For example, the method 2200 is useful to manufacture the semiconductor package 104 of FIGS. 14A-14D. FIGS. 23A-23L3 are a process flow of the method 2200, in accordance with various examples. Accordingly, FIGS. 22, and 23A-23L3 are described in parallel.

The method 2200 includes forming a multi-layer substrate by iteratively plating a metal layer, applying build-up film to the metal layer, and thinning the build-up film (2202). The multi-layer substrate has a top surface including first and second contacts (2202). The multi-layer substrate may be formed by another technique than that described in FIG. 22. For example, multi-layer substrates such as ball grid array substrates and embedded trace substrates (ETSs) are contemplated and included in the scope of this disclosure. FIG. 23A depicts the plating of metal layers 2302 and 2304 on a carrier 2300. The metal layers 2302 and 2304 may be considered as a single metal layer having two metal members, with one of the metal members being a metal trace and the other metal member being a metal via. Alternatively, the metal layers 2302 and 2304 may be considered as distinct metal layers in contact with each other. The metal layer 2302 may be formed by depositing a seed layer (e.g., copper seed layer) on the surface of the carrier 2300, but such a seed layer is not expressly depicted, to facilitate clarity. FIG. 23B depicts the application of a dielectric 2306, such as ABF. FIG. 23C depicts a grinding of the dielectric 2306 to thin the dielectric 2306 until a top surface of the metal layer 2304 is exposed. FIG. 23D depicts the plating of two additional metal layers 2308 and 2310. FIG. 23E depicts the application of dielectric 2312 (e.g., ABF), and FIG. 23F depicts the grinding of the dielectric 2312 to expose the top surface of the metal layer 2310. FIG. 23G depicts the plating of two additional metal layers 2314 and 2316. FIG. 23H depicts the application of dielectric 2318 (e.g., ABF), and FIG. 23I depicts the grinding of the dielectric 2318 to expose the top surface of the metal layer 2316. In this way, a multi-layer substrate is formed. Although FIG. 23I depicts a substrate having a specific number of metal layers, substrates having any suitable number of metal layers are contemplated and included in the scope of this disclosure.

The method 2200 includes coupling a semiconductor die to the first contact (2204). FIG. 23J depicts a semiconductor die 2320 coupled to the metal layer 2316. The top surface(s) of the metal layer 2316 to which the semiconductor die 2320 couples may be considered the first contact(s) of step 2204. The semiconductor die 2320 may couple to the metal layer 2316 by solder bumps or any other suitable bonding member or technique.

The method 2200 includes positioning a lead frame above the semiconductor die and the multi-layer substrate, with the lead frame including an antenna and a conductive member (2206), and coupling a bent conductive member of the lead frame to the second contact (2208). FIG. 23K1 is a cross-sectional view of the structure of FIG. 23J, except that a lead frame is positioned above the structure of FIG. 23J, and the clips 1416 and the protrusions 1420 (FIG. 23K3) are coupled to and/or oriented toward the structure of FIG. 23J, as shown in FIG. 14B.FIGS. 23K2 and 23K3 are top-down and perspective views of the structure of FIG. 23K1, respectively.

The method 2200 includes applying a mold compound to contact the multi-layer substrate, the semiconductor die, the antenna, and the conductive member (2210). FIGS. 23L1-23L3 are cross-sectional, top-down, and perspective views, respectively, of the structure of FIGS. 23K1-23K3, but with the mold compound 1412 applied. The molded structure may then be singulated to produce individual semiconductor packages 104 (2212).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Uses of the term “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a die pad extending in a horizontal direction;
a semiconductor die coupled to the die pad, the semiconductor die having a device side in which circuitry is formed;
a conductive terminal coupled to the device side of the semiconductor die by a bond wire;
an antenna vertically distanced from the die pad and extending in the horizontal direction;
a metal member extending from the antenna in the horizontal direction;
a conductive member coupling the antenna to the conductive terminal; and
a mold compound contacting the die pad, the semiconductor die, the conductive terminal, the antenna, the metal member, and the conductive member, a portion ofthe conductive terminal and the metal member exposed on one or more exterior lateral surfaces of the mold compound.

2. The semiconductor package of claim 1, wherein the antenna is a patch antenna.

3. The semiconductor package of claim 1, wherein the antenna is a loop antenna.

4. The semiconductor package of claim 1, wherein the antenna is a meander line antenna.

5. The semiconductor package of claim 1, wherein the conductive member is a downset clip.

6. The semiconductor package of claim 1, wherein the metal member is a tie bar.

7. The semiconductor package of claim 6, wherein the tie bar, the antenna, and the conductive member are a monolithic structure.

8. The semiconductor package of claim 1, wherein the antenna is a first antenna, and further comprising a second antenna coupled to the metal member, the metal member including a cavity in between the first and second antennas.

9. The semiconductor package of claim 8, wherein the first antenna is coupled to the metal member by first and second tie bars.

10. The semiconductor package of claim 9, wherein the first antenna is suspended in an opening in the metal member by the first and second tie bars.

11. The semiconductor package of claim 10, wherein the opening is a first opening, and wherein the metal member includes a bar that is approximately parallel to the first and second tie bars and that includes a second opening, a vertical line extending through the second opening and through an end of the conductive member that is distal to the antenna.

12. The semiconductor package of claim 1, wherein the conductive member is coupled to the conductive terminal by solder or die attach material, and wherein the conductive member, the metal member, and the antenna are a monolithic structure.

13. A semiconductor package, comprising:
a multi-layer substrate including multiple metal layers and a solid dielectric layer positioned between the multiple metal layers, the multi-layer substrate including first and second contacts coupled to the multiple metal layers;
a semiconductor die having a device side in which circuitry is formed, the device side of the semiconductor die coupled to the first contact;
an antenna vertically distanced from the multi-layer substrate and extending in a horizontal direction;
a metal member extending from the antenna in the horizontal direction;
a conductive member coupling the antenna to the second contact; and
a mold compound contacting the multi-layer substrate, the semiconductor die, the antenna, the metal member, and the conductive member, the metal member exposed on one or more exterior lateral surfaces of the mold compound.

14. The semiconductor package of claim 13, wherein the conductive member is a downset clip.

15. The semiconductor package of claim 13, wherein the antenna is a first antenna, and further comprising a second antenna coupled to the metal member, the metal member including a protrusion in between the first and second antennas and extending toward the semiconductor die in a vertical direction, the metal member including an opening in between the first and second antennas.

16. The semiconductor package of claim 13, wherein the antenna is coupled to the metal member by first and second tie bars.

17. The semiconductor package of claim 16, wherein the first and second tie bars suspend the antenna in an opening in the metal member.

18. The semiconductor package of claim 13, wherein the antenna is one of a patch antenna, a loop antenna, and a meander line antenna.

19. A method for manufacturing a semiconductor package, comprising:
coupling a semiconductor die to a die pad of a first lead frame, the semiconductor die having a device side in which circuitry is formed, the first lead frame including a conductive terminal;
coupling a bond wire to the device side of the semiconductor die and to the conductive terminal;
positioning a second lead frame above the semiconductor die and the first lead frame, the second lead frame including an antenna and a conductive member;
coupling a bent conductive member of the second lead frame to the conductive terminal; and
applying a mold compound covering the semiconductor die, the bond wire, and the first and second lead frames, the conductive terminal exposed on an exterior lateral surface of the mold compound.

20. The method of claim 19, wherein the antenna is a patch antenna and is coupled to a metal member of the second lead frame by multiple tie bars.

21. The method of claim 19, wherein the antenna is a first antenna, and wherein the second lead frame includes a second antenna and a cavity in between the first and second antennas.

22. The method of claim 21, wherein the second lead frame includes a protrusion extending toward the semiconductor die, the protrusion in between the first and second antennas.

23. The method of claim 19, wherein the second lead frame includes a bar having an opening, and wherein a vertical line extends through the opening and an end of the bent conductive member distal to the antenna.
